(19) United States
(12) Patent Application Publication
(10) Pub. No.: US 2026/0181862 A1
(43) Pub. Date: Jun. 25, 2026

(54) SEMICONDUCTOR DEVICE

(71) Applicant: Samsung Electronics Co., Ltd., Suwon-si (KR)

(72) Inventors: YANGDOO KIM, Suwon-si (KR); Chanmin KANG, Suwon-si (KR); GWANG-HYUN BAEK, Suwon-si (KR); Youngsik LEE, Suwon-si (KR); JINKWAN LEE, Suwon-si (KR); JE-WOO HAN, Suwon-si (KR)

(21) Appl. No.: 19/352,225

(22) Filed: Oct. 7, 2025

(30) Foreign Application Priority Data
Dec. 20, 2024 (KR) 10-2024-0192284

(51) Int. Cl. H10B 12/00

(52) U.S. Cl. CPC H10B 12/30; H10B 12/05

(57) ABSTRACT

A semiconductor device includes a gate electrode extending on a substrate in a first direction, a semiconductor pattern extending in a second direction crossing the first direction, and penetrating the gate electrode, and a gate insulating layer between the gate electrode and the semiconductor pattern. The semiconductor pattern has side surfaces facing away from each other in the first direction, and an upper surface and a lower surface facing away from each other in a third direction. The gate electrode includes conductive sub-patterns respectively disposed on the side surfaces of the semiconductor pattern, and spaced apart from each other in the first direction and a conductive pattern extending in the first direction to cover the upper and lower surfaces of the semiconductor pattern and to cover the conductive sub-patterns. The conductive sub-patterns have a work-function different from that of the conductive pattern.

### CROSS-REFERENCE TO RELATED APPLICATIONS

This U.S. non-provisional patent application claims priority under 35 U.S.C. § 119 of Korean Patent Application No. 10-2024-0192284, filed on Dec. 20, 2024, the entire contents of which are hereby incorporated by reference.

### BACKGROUND

The present disclosure herein relates to a semiconductor device and a method for manufacturing the same, and more particularly, to a semiconductor device including field effect transistors vertically stacked and a method for manufacturing the same.

A semiconductor device includes an integrated circuit composed of metal-oxide-semiconductor field effect transistors (MOSFETs). As the size and design rules of the semiconductor device are gradually decreasing, scaling down of the MOS field effect transistors is also gradually being accelerated. As the MOS field effect transistors are scaled down, operation characteristics of the semiconductor device may be deteriorated. Accordingly, for high-integration of the semiconductor device, research on various structures in which the MOS field effect transistors are stacked on the substrate in a vertical direction is being carried out. In addition, research on various methods for overcoming limitations caused by high-integration of the semiconductor device and forming the semiconductor device with more excellent performance is being conducted.

### SUMMARY

The present disclosure provides a semiconductor device with improved electrical characteristics and a method for manufacturing the same.

The present disclosure also provides a semiconductor device easily high-integrated and a method for manufacturing the same.

An embodiment of the inventive concept provides a semiconductor device including a gate electrode extending on a substrate in a first direction, a semiconductor pattern extending in a second direction crossing the first direction, and penetrating the gate electrode. The first direction and the second direction are parallel to an upper surface of the substrate and cross each other. The semiconductor device further includes a gate insulating layer between the gate electrode and the semiconductor pattern. The semiconductor pattern has side surfaces facing away from each other in the first direction, and an upper surface and a lower surface facing each other in a third direction perpendicular to the upper surface of the substrate. The gate electrode includes conductive sub-patterns each disposed on the side surfaces of the semiconductor pattern, and spaced apart from each other in the first direction, and a conductive pattern extending in the first direction to cover the upper surface and the lower surface of the semiconductor pattern and to cover the conductive sub-patterns, and the conductive sub-patterns have a work-function different from that of the conductive pattern.

In an embodiment of the inventive concept, a semiconductor device includes a gate electrode extending on a substrate in a first direction, and a semiconductor pattern extending in a second direction crossing the first direction, and penetrating the gate electrode, wherein the first direction and the second direction are parallel to an upper surface of the substrate, and cross each other, the semiconductor pattern includes a first contact region and a second contact region disposed on opposite sides of the gate electrode in the second direction, and an active region overlapping the gate electrode as viewed from the first and third directions, and interposed between the first contact region and the second contact region, the active region includes a first boundary region adjacent to the first contact region, a second boundary region adjacent to the second contact region, and a channel region between the first boundary region and the second boundary region, the gate electrode includes first conductive sub-patterns spaced apart from each other in the first direction with the first boundary region of the semiconductor pattern therebetween, and a conductive pattern extending in the first direction to surround the active region of the semiconductor pattern, and to cover the first conductive sub-patterns, and the first conductive sub-patterns are interposed between the conductive pattern and the first boundary region of the semiconductor pattern, and have a work-function different from that of the conductive pattern.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram illustrating a semiconductor device according to some embodiments of the inventive concept;

FIG. 2 is a perspective view schematically illustrating a semiconductor device according to some embodiments of the inventive concept;

FIG. 3 is a plan view of a semiconductor device according to some embodiments of the inventive concept;

FIG. 4 is a cross-sectional view taken along A-A′ of FIG. 3;

FIG. 5 is a cross-sectional view taken along B-B′, C-C′ and D-D′ of FIG. 3;

FIG. 6 is an enlarged diagram of part P1 of FIG. 4;

FIG. 7 is an enlarged diagram of parts P2 and P3 of FIG. 5;

FIGS. 8, 11, 14, 17, 20, 23, 27, 30, 33, 35 and 37 are plan views illustrating a method for manufacturing a semiconductor device according to some embodiments of the inventive concept;

FIGS. 9, 12, 15, 18, 21, 24, 28, 31, 34, 36 and 38 are cross-sectional views taken along A-A′ of FIGS. 8, 11, 14, 17, 20, 23, 27, 30, 33, 35 and 37;

FIGS. 10, 13, 16, 19, 22, 25, 29 and 32 are cross-sectional views taken along B-B′, C-C′ and D-D′ of FIGS. 8, 11, 14, 17, 20, 23, 27 and 30; and

FIG. 26 is an enlarged diagram of part P4 of FIG. 25 and part P5 of FIG. 29.

### DETAILED DESCRIPTION

Hereinafter, the inventive concept will be described in detail by describing embodiments of the inventive concept with reference to the accompanying drawings.

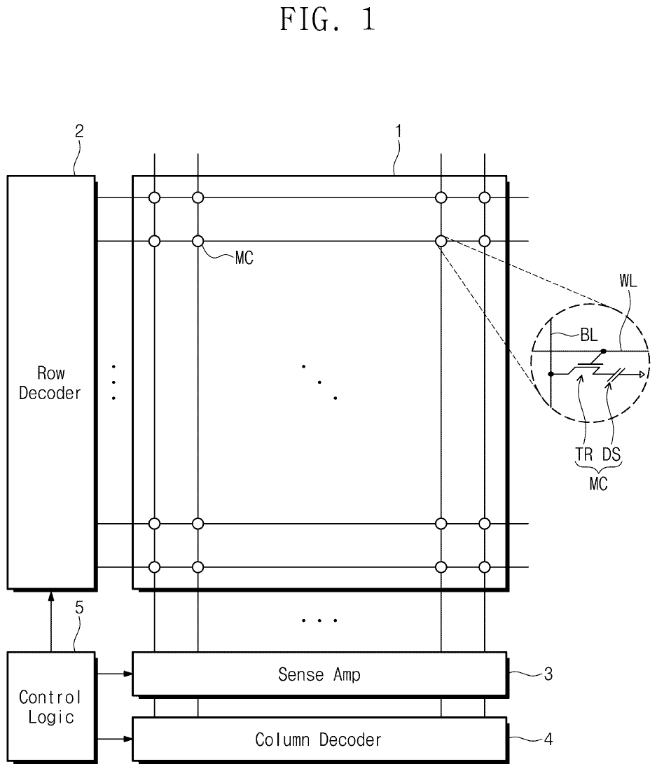

FIG. 1 is a block diagram illustrating a semiconductor device according to some embodiments of the inventive concept.

Referring to FIG. 1, the semiconductor device may include a memory cell array 1, a row decoder 2, a sense amplifier 3, a column decoder 4 and a control logic 5.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “intrinsic,” “undoped,” “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

The memory cell array 1 may include a plurality of memory cells MC two-dimensionally or three-dimensionally arranged. Each of the memory cells MC may be connected between a word line WL and a bit line BL crossing each other. Each of the memory cells MC may include a selection element TR and a data storage element DS. The selection element TR and the data storage element DS may be electrically connected to each other. The selection element TR may be connected to the word line WL and the bit line BL, and may be provided to a point at which the word line WL and the bit line BL cross each other.

The selection element TR may include a field effect transistor. The data storage element DS may include a capacitor, a magnetic tunnel junction pattern, or a variable resistor. When the selection element TR includes the field effect transistor, a gate terminal of the transistor may be connected to the word line WL, and each of source/drain terminals of the transistor may be connected to the bit line BL and a corresponding one of the data storage element DS.

The row decoder 2 may select any one of the word lines WL of the memory cell array 1 by decoding an address input from an external circuit thereto. The address decoded by the row decoder 2 may be provided to a row driver (not shown), and the row driver may provide a selected word line WL and unselected word lines WL with a predetermined voltage in response to controls of control circuits.

The sense amplifier 3 may sense, amplify and output a voltage difference between a selected bit line BL and a reference bit line according to the address decoded by the column decoder 4.

The column decoder 4 may provide a data transfer path between the sense amplifier 3 and an external element (for example, a memory controller). The column decoder 4 may select any one among the bit lines BL of the memory cell array 1 by decoding the address input from the external circuit thereto. The control logic 5 may generate a control signal that controls an operation of writing a data to the memory cell array 1 or reading the data from the memory cell array 1.

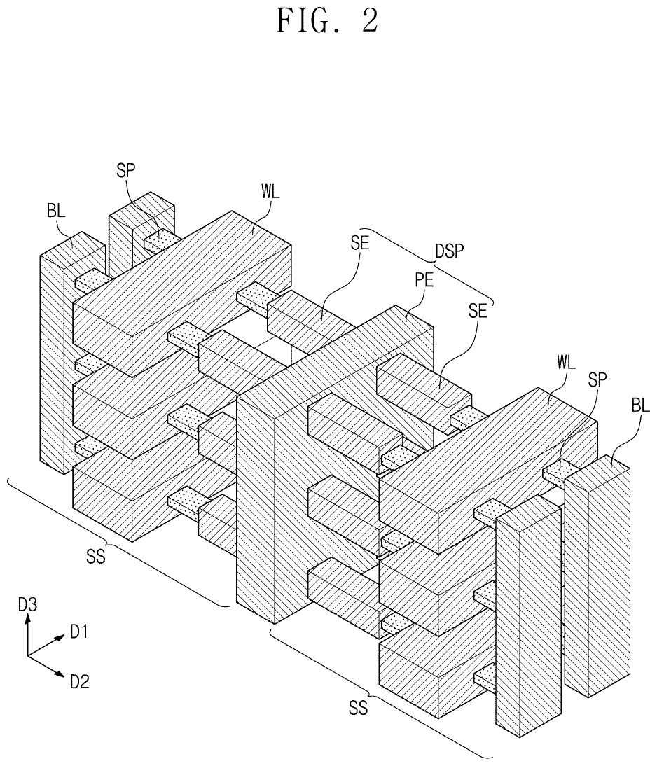

FIG. 2 is a perspective view schematically illustrating the semiconductor device according to some embodiments of the inventive concept.

Referring to FIG. 2, the semiconductor device may include stack structures SS adjacent to each other, and a plate electrode PE between the stack structures SS. The plate electrode PE may extend in a first direction D1, and the stack structures SS may be spaced apart from each other in a second direction D2 with the plate electrode PE therebetween. The plate electrode PE may extend along a third direction D3 vertical (perpendicular)_to all of the first direction D1 and the second direction D2.

Each of the stack structures SS may include a plurality of word lines WL extending in the first direction D1 and spaced apart from each other in the third direction D3. Each of the stack structures SS may further include a plurality of semiconductor patterns SP extending in the second direction D2 and spaced apart from each other in the first direction D1 and the third direction D3. Each of the stack structures SS may further include a plurality of bit lines BL extending in the third direction D3 and spaced apart from each other in the first direction D1. Each of the stack structures SS may further include a plurality of storage electrodes SE respectively connected to the plurality of semiconductor patterns SP.

A set of the semiconductor patterns SP, spaced apart from each other in the first direction D1, among the plurality of semiconductor patterns SP may extend in the second direction D2 to penetrate a corresponding word line WL among the plurality of word lines WL. A set of the semiconductor patterns SP, spaced apart from each other in the third direction D3, among the plurality of semiconductor patterns SP may extend in the second direction D2 to respectively penetrate the plurality of word lines WL. Each of the bit lines BL may extend in the third direction D3 to be connected, in common, to the semiconductor patterns SP spaced apart from each other in the third direction D3. The plurality of storage electrodes SE may be connected to the plate electrode PE in common. The stack structures SS may be disposed so as to be mirror-symmetric with the plate electrode PE therebetween. The plurality of storage electrodes SE and the plate electrode PE may constitute a data storage pattern DSP.

The stack structures SS and the plate electrode PE may constitute the memory cell array 1 of FIG. 1. Each semiconductor pattern SP and a corresponding word line WL connected thereto may correspond to the selection element TR and the word line WL of FIG. 1. A corresponding bit line BL connected to each semiconductor pattern SP may correspond to the bit line BL of FIG. 1. The plate electrode PE and the storage electrodes SE corresponding and connected to each semiconductor pattern SP may constitute the data storage pattern DS of FIG. 1.

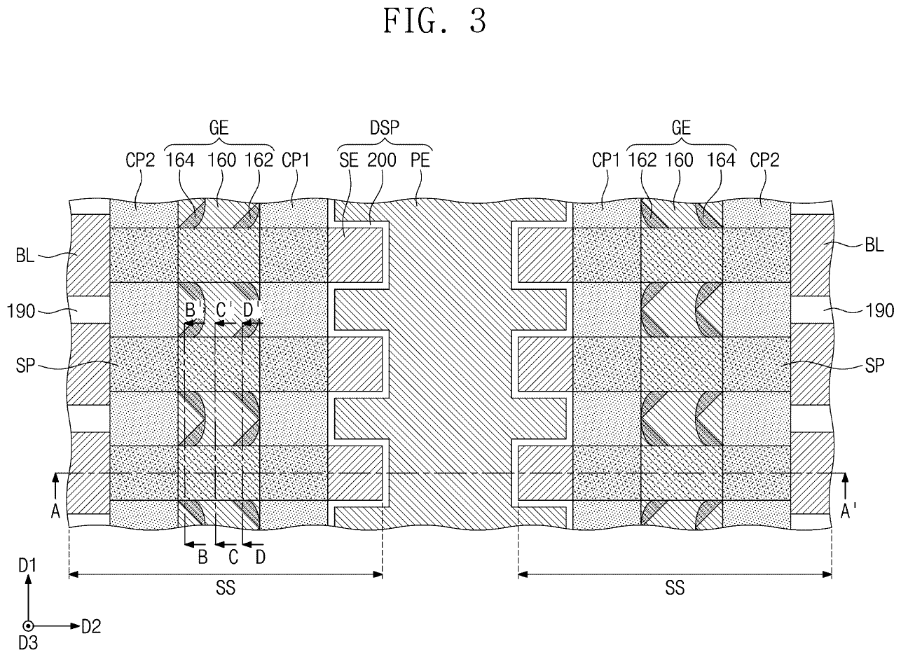

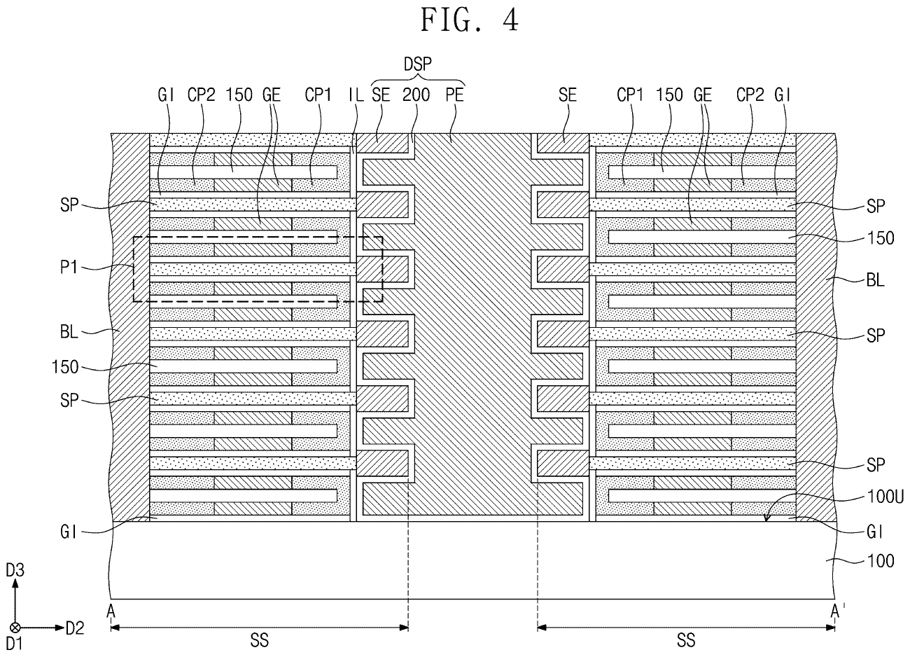

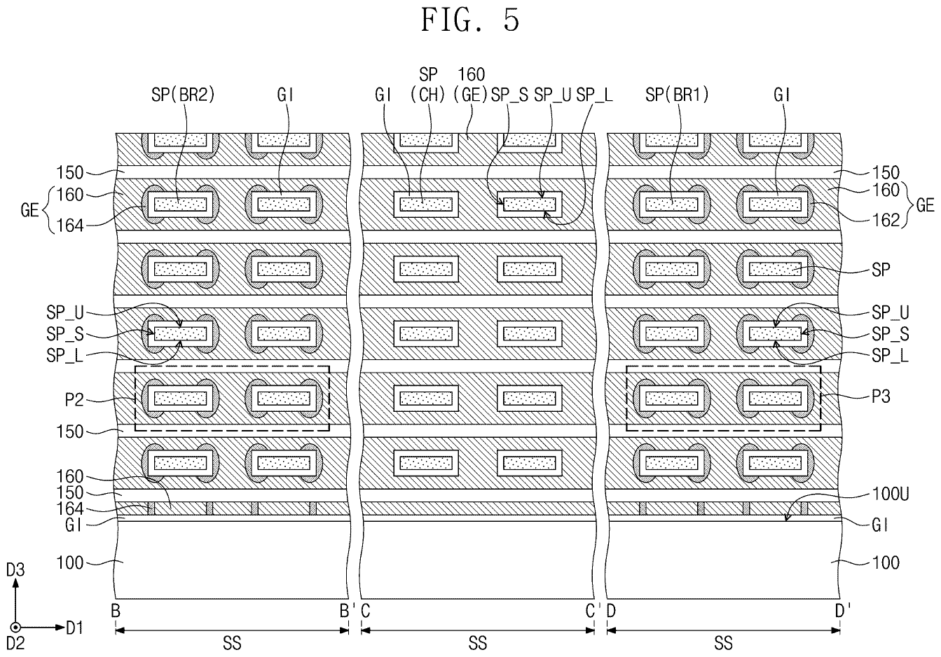

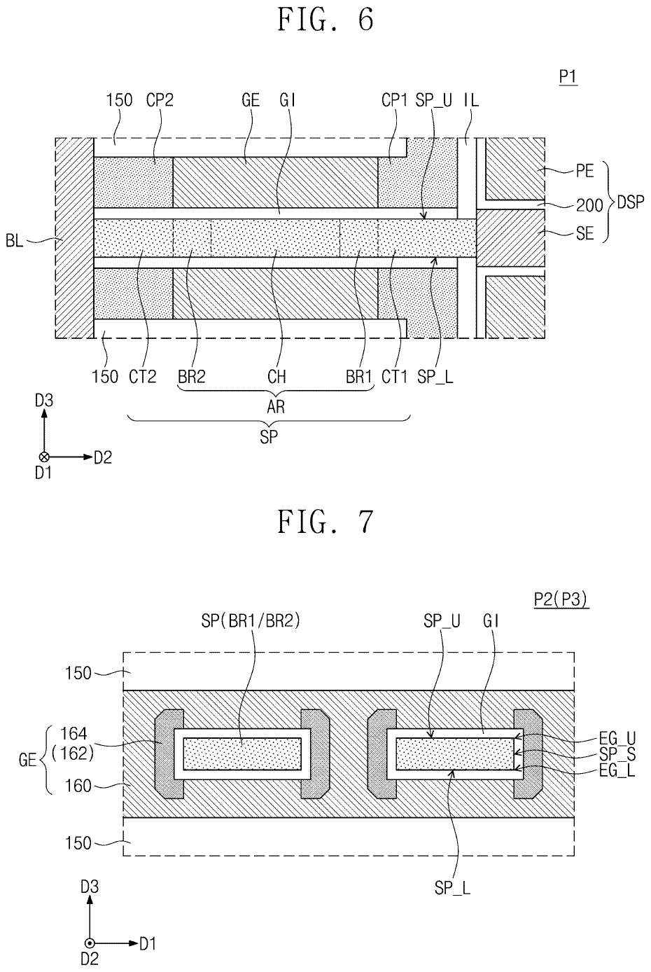

FIG. 3 is a plan view of the semiconductor device according to some embodiments of the inventive concept. FIG. 4 is a cross-sectional view taken along A-A′ of FIG. 3, and FIG. 5 is a cross-sectional view taken along B-B′, C-C′ and D-D′ of FIG. 3. FIG. 6 is an enlarged diagram of part P1 of FIG. 4, and FIG. 7 is an enlarged diagram of parts P2 and P3 of FIG. 5.

Referring to FIGS. 3, 4, and 6, the stack structures SS and the plate electrode PE may be disposed on a substrate 100. The substrate 100 may be a semiconductor substrate, an insulating substrate, a silicon-on-insulator (SOI) substrate or a germanium-on-insulator (GOI) substrate. For example, the semiconductor substrate may be a silicon substrate, a germanium substrate or a silicon-germanium substrate. The plate electrode PE may extend in the first direction D1, and the stack structures SS may be spaced apart from each other in the second direction D2 with the plate electrode PE therebetween. The first direction D1 and the second direction D2 may be parallel to an upper surface 100U of the substrate 100 and may cross each other. The plate electrode PE may extend in the third direction D3 vertical (perpendicular) to the upper surface 100U of the substrate 100 between the stack structures SS.

Each of the stack structures SS may include the plurality of semiconductor patterns SP extending in the second direction D2. The plurality of semiconductor patterns SP may be spaced apart from the upper surface 100U of the substrate 100 along the third direction D3, and may be spaced apart from each other in the first direction D1 and the third direction D3. The plurality of semiconductor patterns SP may include at least one of a semiconductor material, oxide semiconductor or a two-dimensional semiconductor material. For example, the plurality of semiconductor patterns SP may include at least one of silicon (for example, single-crystalline silicon), germanium or silicon-germanium. For example, the plurality of semiconductor patterns SP may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or a combination thereof. For example, the plurality of semiconductor patterns SP may include indium-gallium-zinc oxide (IGZO). For example, the plurality of semiconductor patterns SP may include graphene, carbon nanotube or a combination thereof.

Each of the stack structures SS may include a plurality of gate electrodes GE extending in the first direction D1, and spaced apart from each other in the third direction D3. The plurality of gate electrodes GE may function as the word lines WL of FIGS. 1 and 2. The plurality of gate electrodes GE may be spaced apart from the upper surface 100U of the substrate 100 along the third direction D3. According to some embodiments, a lowermost gate electrode GE among the plurality of gate electrodes GE and an uppermost gate electrode GE among the plurality of gate electrodes GE may be dummy gate electrodes. As used herein, the term “dummy” is used to refer to a component that has the same or similar structure and shape as other similarly named components but does not have a substantial function as such components. A dummy gate electrode, e.g., may be a conductor having a similar shape and size as a normal gate electrode but not be used to access memory cells MC. In some examples, a dummy gate electrode may be electrically floating.

A set of the semiconductor patterns SP, spaced apart from each other in the first direction D1, among the plurality of semiconductor patterns SP may extend in the second direction D2 to penetrate a corresponding gate electrode GE among the plurality of gate electrodes GE. A set of the semiconductor patterns SP, spaced apart from each other in the third direction D3, among the plurality of semiconductor patterns SP may extend in the second direction D2 to respectively penetrate the plurality of gate electrodes GE.

Each of the stack structures SS may further include a plurality of mold patterns 150 interposed between the plurality of gate electrodes GE and spaced apart from each other in the third direction D3. The plurality of mold patterns 150 may extend between the plurality of gate electrodes GE in the first direction D1. The plurality of gate electrodes GE and the plurality of mold patterns 150 may be alternately disposed along the third direction D3. The plurality of mold patterns 150 may extend between the plurality of semiconductor patterns SP along the second direction D2. The plurality of mold patterns 150 may include an insulating material, and may include, for example, silicon oxide, silicon nitride and/or silicon oxynitride.

Each of the stack structures SS may further include a first capping pattern CP1 and a second capping pattern CP2 disposed on both sides (e.g., opposite sides) of each of the plurality of gate electrodes GE. The first capping pattern CP1 and the second capping pattern CP2 may extend in the first direction D1. Each of the plurality of semiconductor patterns SP may extend in the second direction D2 to penetrate the first capping pattern CP1 and the second capping pattern CP2. Each of the plurality of gate electrodes GE, the first capping pattern CP1 and the second capping pattern CP2 may be interposed between a pair of mold patterns 150, next to each other in the third direction D3, among the plurality of mold patterns 150. The first and second capping patterns CP1 and CP2 may include an insulating material, and may include, for example, silicon oxide, silicon nitride and/or silicon oxynitride.

Each of the stack structures SS may further include a gate insulating layer GI interposed between each of the plurality of semiconductor patterns SP and each of the plurality of gate electrodes GE. Each of the plurality of semiconductor patterns SP may be spaced apart from each of the plurality of gate electrodes GE with the gate insulating layer GI therebetween. The gate insulating layer GI may extend in the second direction D2 to be interposed between the first capping pattern CP1 and each of the plurality of semiconductor patterns SP, and between the second capping pattern CP2 and each of the plurality of semiconductor patterns SP. Each of the plurality of semiconductor patterns SP may be spaced apart from the first capping pattern CP1 and the second capping pattern CP2 with the gate insulating layer GI therebetween. The gate insulating layer GI may be interposed between the substrate 100 and the lowermost gate electrode GE. A lowermost first capping pattern CP1 and a lowermost second capping pattern CP2 may be disposed on both sides (e.g., opposite sides) of the lowermost gate electrode GE, and the gate insulating layer GI may extend between the substrate 100 and the lowermost first capping pattern CP1, and between the substrate 100 and the lowermost second capping pattern CP2. For example, the gate insulating layer GI may include at least one of silicon oxide or a high-dielectric material. The high-dielectric material may be a material having a higher dielectric constant than silicon oxide, and may include, for example, metal oxide or metal oxynitride. For example, the high dielectric material may include at least one of HfO₂, HfSiO, HfSiON, HfTaO, HfTiO, HfZrO, ZrO₂ or Al₂O₃.

Each of the stack structures SS may further include a plurality of bit lines BL spaced apart from each other in the first direction D1 and extending in the third direction D3. Each of the plurality of bit lines BL may extend in the third direction D3 to be electrically connected to the semiconductor patterns SP spaced apart from each other in the third direction D3. The plurality of bit lines BL may include at least one of a doped semiconductor material (e.g., doped silicon, doped germanium, or the like), metal (e.g., Ti, Mo, W, Cu, Al, Ta, Ru, Ir, Co, or the like), metal silicide (e.g., silicide of Ti, Mo, W, Cu, Al, Ta, Ru, Ir, Co, or the like), or conductive metal nitride (e.g., nitride of Ti, Mo, W, Cu, Al, Ta, Ru, Ir, Co, or the like). According to some embodiments, the plurality of bit lines BL may include a carbon-based two-dimensional material (for example, graphene), a carbon-based three-dimensional material (for example, carbon nanotube) or a combination thereof.

Each of the stack structures SS may further include a buried insulating layer 190 extending between the plurality of bit lines BL in the third direction D3. Each of the plurality of bit lines BL may penetrate the buried insulating layer 190 along the third direction D3. The buried insulating layer 190 may include an insulating material, and may include, for example, silicon oxide, silicon nitride and/or silicon oxynitride.

Each of the stack structures SS may further include a plurality of storage electrodes SE respectively connected to the plurality of semiconductor patterns SP. The plurality of storage electrodes SE may be spaced apart from each other in the first direction D1 and the third direction D3. The plurality of storage electrodes SE may be spaced apart from the plurality of bit lines BL in the second direction D2, and the plurality of semiconductor patterns SP, the plurality of gate electrodes GE, the first and second capping patterns CP1 and CP2, the plurality of mold patterns 150 and the gate insulating layer GI may be disposed between the plurality of storage electrodes SE and the plurality of bit lines BL. The plurality of storage electrodes SE may be electrically connected to the plate electrode PE.

The plurality of storage electrodes SE and the plate electrode PE may include at least one of impurity-doped silicon (Si), impurity-doped silicon germanium (SiGe), metal (e.g., Ti, Mo, W, Cu, Al, Ta, Ru, Ir, Co, Pt, Au, Ag, or the like), metal nitride (e.g., nitride of Ti, Mo, W, Cu, Al, Ta, Ru, Ir, Co, Pt, Au, Ag, or the like, titanium silicon nitride (e.g., TiSiN), titanium aluminum nitride (e.g., TiAlN), tantalum aluminum nitride (e.g., TaAlN), or the like), conductive oxide (e.g., PtO, RuO₂, IrO₂, SRO (SrRuO₃), BSRO ((Ba,Sr)RuO₃), CRO (CaRuO₃), or LSCo), or metal silicide.

Each of the stack structures SS may further include a dielectric layer 200 interposed between the plurality of storage electrodes SE and the plate electrode PE. The dielectric layer 200 may conformally cover each of the plurality of storage electrodes SE, and may extend between the plurality of storage electrodes SE along the first direction D1 and the third direction D3. Each of the stack structures SS may further include an insulating layer IL interposed between the first capping pattern CP1 and the dielectric layer 200 between the plurality of storage electrodes SE. The dielectric layer 200 may extend between the substrate 100 and the plate electrode PE along the second direction D2. The plate electrode PE may be spaced apart from the substrate 100 with the dielectric layer 200 therebetween.

Each of the plurality of storage electrodes SE may be spaced apart from the plate electrode PE with the dielectric layer 200 therebetween. The plurality of storage electrodes SE, the plate electrode PE and the dielectric layer 200 may constitute the data storage pattern DSP, and the data storage pattern DSP may be, for example, a capacitor. The dielectric layer 200 may include at least one of metal oxide such as HfO₂, ZrO₂, Al₂O₃, La₂O₃, Ta₂O₃, or TiO₂ or a dielectric material having a perovskite structure such as SrTiO₃ (STO), (Ba,Sr)TiO₃ (BST), BaTiO₃, PZT, or PLZT. The insulating layer IL may include an insulating material, and may include, for example, silicon oxide, silicon nitride and/or silicon oxynitride. The stack structures SS may be disposed so as to be mirror-symmetric with the plate electrode PE therebetween.

Each semiconductor pattern SP may extend in the second direction D2 to penetrate the gate electrode GE, the first capping pattern CP1 and the second capping pattern CP2 corresponding thereto. The semiconductor pattern SP may include a first contact region CT1 and a second contact region CT2 disposed on both sides (e.g., opposite sides) of the gate electrode GE, and an active region AR between the first contact region CT1 and the second contact region CT2. As viewed from the first and/or third directions, the active region AR may overlap the gate electrode GE. As viewed from the first and/or third directions, the first contact region CT1 may overlap the first capping pattern CP1, and the second contact region CT2 may overlap the second capping pattern CP2. The active region AR may include a first boundary region BR1 adjacent to the first contact region CT1, a second boundary region BR2 adjacent to the second contact region CT2, and a channel region CH between the first boundary region BR1 and the second boundary region BR2.

The first contact region CT1 and the second contact region CT2 may have an N-type or a P-type conductive type, and may be regions injected with an N-type or a P-type dopant (or impurity or charge carrier impurity). The first contact region CT1 and the second contact region CT2 may have the same conductive type as each other. The first contact region CT1 and the second contact region CT2 may be respectively referred to as a first source/drain region and a second source/drain region. The channel region CH may be an intrinsic semiconductor region. At least a portion of the first boundary region BR1 may have the same conductive type as the first contact region CT1, and may include the same dopant as the first contact region CT1. At least a portion of the second boundary region BR2 may have the same conductive type as the second contact region CT2, and may include the same dopant as the second contact region CT2.

In some embodiments, the first boundary region BR1 may have the same conductive type as the first contact region CT1, and a doping concentration of the CT1 may be greater than that of the first boundary region BR1. The second boundary region BR2 may have the same conductive type as the second contact region CT2, and a doping concentration of the second contact region CT2 may be greater than that of second boundary region BR2. Doping concentrations of the first and second contact regions CT1 and CT2 may be greater than that of the channel region CH, and doping concentrations of the first and second boundary regions BR1 and BR2 may be greater than that of the channel region CH.

In semiconductor technology, if a semiconductor contains both p-type and n-type impurities (charge carrier impurities), the conductivity-type (or conductive type) of the semiconductor will be determined by which type of impurity is in greater concentration. Therefore, if a semiconductor has both p-type and n-type impurities, the net conductivity type will be determined by the dominant impurity concentration. As used herein, a semiconductor region of a “first conductivity-type” denotes that the dominant impurities in the semiconductor region is (or are) a first conductivity-type impurity, and a “concentration of the first conductivity-type” in the semiconductor region (or a “doping concentration”) refers the net concentration of the impurities in the semiconductor region (i.e., (the amount of first conductivity-type impurities minus the amount of second conductivity-type impurities)/the volume of the semiconductor region).

According to some embodiments, the first contact region CT1 of the semiconductor pattern SP may be connected to a corresponding storage electrode SE, and the second contact region CT2 of the semiconductor pattern SP may be connected to a corresponding bit line BL. According to other embodiments, unlike what is illustrated, the first contact region CT1 of the semiconductor pattern SP may be connected to a corresponding bit line BL, and the second contact region CT2 of the semiconductor pattern SP may be connected to a corresponding storage electrode SE.

Referring to FIGS. 3, 5, 6, and 7, each gate electrode GE may extend in the first direction D1, and may surround the active region AR of a corresponding semiconductor pattern SP. The semiconductor pattern SP may have side surfaces SP_S opposite to each other in the first direction D1, and an upper surface SP_U and a lower surface SP_L opposite to each other in the third direction D3. For example, each of the semiconductor patterns SP may have two opposite side surfaces SP_S that face away from each other in the first direction D1, and each of the semiconductor patterns SP may have the upper surface SP_U and a lower surface SP_L that face away from each other in the third direction D3. The gate electrode GE may cover the upper surface SP_U and the lower surface SP_L of the active region AR of the semiconductor pattern SP, and may extend onto the side surfaces SP_S of the active region AR of the semiconductor pattern SP. The gate electrode GE may have a gate-all-around structure in which the gate electrode GE surrounds the active region AR of the semiconductor pattern SP. The first capping pattern CP1 may extend in the first direction D1, and may surround the first contact region CT1 of the semiconductor pattern SP. The second capping pattern CP2 may extend in the first direction D1, and may surround the second contact region CT2 of the semiconductor pattern SP.

The gate electrode GE may include first conductive sub-patterns 162 respectively disposed on the side surfaces SP_S of the active region AR of the semiconductor pattern SP. The first conductive sub-patterns 162 may be respectively disposed on side surfaces SP_S of the first boundary region BR1 of the semiconductor pattern SP, and may be spaced apart from each other in the first direction D1. The gate electrode GE may further include second conductive sub-patterns 164 respectively disposed on the side surfaces SP_S of the active region AR of the semiconductor pattern SP. The second conductive sub-patterns 164 may be respectively disposed on side surfaces SP_S of the second boundary region BR2 of the semiconductor pattern SP, and may be spaced apart from each other in the first direction D1. The gate electrode GE may further include a conductive pattern 160 extending in the first direction D1 to cover the upper surface SP_U and the lower surface SP_L of the active region AR of the semiconductor pattern SP, and extending onto the side surfaces SP_S of the active region AR of the semiconductor pattern SP to cover the first and second conductive sub-patterns 162 and 164.

According to some embodiments, the first conductive sub-patterns 162 may be omitted, and in this case, the gate electrode GE may include the conductive pattern 160 and the second conductive sub-patterns 164. According to other embodiments, the second conductive sub-patterns 164 may be omitted, and in this case, the gate electrode GE may include the conductive pattern 160 and the first conductive sub-patterns 162.

The first conductive sub-patterns 162 may have a work-function different from that of the conductive pattern 160, and may have a work-function different from that of the first contact region CT1 of the semiconductor pattern SP. The first conductive sub-patterns 162 may have a lower work-function than the conductive pattern 160, and may have a greater work-function than the first contact region CT1 of the semiconductor pattern SP. The first conductive sub-patterns 162 may have an N-type or a P-type conductive type, and may have the same conductive type as the first contact region CT1 of the semiconductor pattern SP. The second conductive sub-patterns 164 may have a work-function different from the conductive pattern 160, and may have a work-function different from that of the second contact region CT2 of the semiconductor pattern SP. The second conductive sub-patterns 164 may have a lower work-function than the conductive pattern 160, and may have a greater work-function than the second contact region CT2 of the semiconductor pattern SP. The second conductive sub-patterns 164 may have an N-type or a P-type conductive type, and may have the same conductive type as the second contact region CT2 of the semiconductor pattern SP.

For example, the first and second conductive sub-patterns 162 and 164 may include polycrystalline silicon. For example, the first and second conductive sub-patterns 162 and 164 may include polycrystalline silicon doped with an N-type or a P-type dopant. The conductive pattern 160 may include metal. For example, the conductive pattern 160 may include at least one of metal (e.g., Ti, Mo, W, Cu, Al, Ta, Ru, Ir, Co, or the like), metal silicide (e.g., silicide of Ti, Mo, W, Cu, Al, Ta, Ru, Ir, Co, or the like), or conductive metal nitride (e.g., nitride of Ti, Mo, W, Cu, Al, Ta, Ru, Ir, Co, or the like).

The gate insulating layer GI may be interposed between the first conductive sub-patterns 162 and the side surfaces SP_S of the first boundary region BR1 of the semiconductor pattern SP, and may extend between the conductive pattern 160 and the upper surface SP_U of the first boundary region BR1 of the semiconductor pattern SP, and between the conductive pattern 160 and the lower surface SP_L of the first boundary region BR1 of the semiconductor pattern SP. The conductive pattern 160 may extend between the first conductive sub-patterns 162 to be in contact with the gate insulating layer GI on the upper surface SP_U and the lower surface SP_L of the semiconductor pattern SP. The first conductive sub-patterns 162 may be interposed between the conductive pattern 160 and the side surfaces SP_S of the first boundary region BR1 of the semiconductor pattern SP, and may be in contact with the gate insulating layer GI on the side surfaces SP_S of the first boundary region BR1 of the semiconductor pattern SP. The first boundary region BR1 of the semiconductor pattern SP may overlap the first conductive sub-patterns 162 along the first direction D1.

Each of the first conductive sub-patterns 162 may extend so as to partially cover the upper surface SP_U of the first boundary region BR1 of the semiconductor pattern SP and the lower surface SP_L of the first boundary region BR1 of the semiconductor pattern SP. Accordingly, each of the first conductive sub-patterns 162 may cover an upper edge EG_U between the upper surface SP_U and each of the side surfaces SP_S of the first boundary region BR1 of the semiconductor pattern SP, and a lower edge EG_L between the lower surface SP_L and each of the side surfaces SP_S of the first boundary region BR1 of the semiconductor pattern SP. Each of the first conductive sub-patterns 162 may cover the gate insulating layer GI on the lower edge EG_L and the upper edge EG_U of the first boundary region BR1 of the semiconductor pattern SP, and may extend so as to partially cover the gate insulating layer GI on the upper surface SP_U and the lower surface SP_L of the first boundary region BR1 of the semiconductor pattern SP. Each of the first conductive sub-patterns 162 may have a c shape on a cross-sectional view.

The gate insulating layer GI may be interposed between the second conductive sub-patterns 164 and the side surfaces SP_S of the second boundary region BR2 of the semiconductor pattern SP, and may extend between the conductive pattern 160 and the upper surface SP_U of the second boundary region BR2 of the semiconductor pattern SP, and between the conductive pattern 160 and the lower surface SP_L of the second boundary region BR2 of the semiconductor pattern SP. The conductive pattern 160 may extend between the second conductive sub-patterns 164 to be in contact with the gate insulating layer GI on the lower surface SP_L and the upper surface SP_U of the semiconductor pattern SP. The second conductive sub-patterns 164 may be interposed between the conductive pattern 160 and the side surfaces SP_S of the second boundary region BR2 of the semiconductor pattern SP, and may be in contact with the gate insulating layer GI on the side surfaces SP_S of the second boundary region BR2 of the semiconductor pattern SP. The second boundary region BR2 of the semiconductor pattern SP may overlap the second conductive sub-patterns 164 along the first direction D1.

Each of the second conductive sub-patterns 164 may extend so as to partially cover the upper surface SP_U of the second boundary region BR2 of the semiconductor pattern SP and the lower surface SP_L of the second boundary region BR2 of the semiconductor pattern SP. Accordingly, each of the second conductive sub-patterns 164 may cover an upper edge EG_U between the upper surface SP_U and each of the side surfaces SP_S of the second boundary region BR2 of the semiconductor pattern SP, and a lower edge EG_L between the lower surface SP_L and each of the side surfaces SP_S of the second boundary region BR2 of the semiconductor pattern SP. Each of the second conductive sub-patterns 164 may cover the gate insulating layer GI on the lower edge EG_L and the upper edge EG_U of the second boundary region BR2 of the semiconductor pattern SP, and may extend so as to partially cover the gate insulating layer GI on the lower surface SP_L and the upper surface SP_U of the second boundary region BR2 of the semiconductor pattern SP. Each of the second conductive sub-patterns 164 may have a c shape on a cross-sectional view.

The gate insulating layer GI may extend between the conductive pattern 160 and each of the side surfaces SP_S of the channel region CH of the semiconductor pattern SP, between the conductive pattern 160 and the upper surface SP_U of the channel region CH of the semiconductor pattern SP, and between the conductive pattern 160 and the lower surface SP_L of the channel region CH of the semiconductor pattern SP. The conductive pattern 160 may be in contact with the gate insulating layer GI on side surfaces SP_S, an upper surface SP_U and a lower surface SP_L of the channel region CH of the semiconductor pattern SP. The channel region CH of the semiconductor pattern SP may not overlap the first conductive sub-patterns 162 and the second conductive sub-patterns 164 along the first direction D1. The first conductive sub-patterns 162 may be spaced apart from the second conductive sub-patterns 164 along the second direction D2.

Due to a difference between a work-function of the first contact region CT1 of the semiconductor pattern SP and a work-function of the conductive pattern 160 of the gate electrode GE, an electric field may be formed between the first contact region CT1 of the semiconductor pattern SP and the conductive pattern 160 of the gate electrode GE, and thus gate-induced drain leakage (GIDL) may occur between the first contact region CT1 of the semiconductor pattern SP and the conductive pattern 160 of the gate electrode GE. Similarly, due to a difference between a work-function of the second contact region CT2 of the semiconductor pattern SP and a work-function of the conductive pattern 160 of the gate electrode GE, an electric field may be formed between the second contact region CT2 of the semiconductor pattern SP and the conductive pattern 160 of the gate electrode GE, and thus gate-induced drain leakage (GIDL) may occur between the second contact region CT2 of the semiconductor pattern SP and the conductive pattern 160 of the gate electrode GE.

According to the inventive concept, the gate electrode GE may include the first and second conductive sub-patterns 162 and 164 having different work-functions different from that of the conductive pattern 160. The first conductive sub-patterns 162 may be respectively disposed on the side surfaces SP_S of the first boundary region BR1 of the semiconductor pattern SP. The first conductive sub-patterns 162 may have a work-function different from those of the conductive pattern 160 and the first contact region CT1 of the semiconductor pattern SP. For example, the first conductive sub-patterns 162 may have a lower work-function than the conductive pattern 160, and may have a greater work-function than the first contact region CT1 of the semiconductor pattern SP. Accordingly, an electric field generated between the first contact region CT1 of the semiconductor pattern SP and the conductive pattern 160 of the gate electrode GE may be minimized, and as a result, gate-induced drain leakage (GIDL) between the first contact region CT1 of the semiconductor pattern SP and the conductive pattern 160 of the gate electrode GE may be prevented or suppressed. The second conductive sub-patterns 164 may be respectively disposed on the side surfaces SP_S of the second boundary region BR2 of the semiconductor pattern SP. The second conductive sub-patterns 164 may have a work-function different from those of the conductive pattern 160 and the second contact region CT2 of the semiconductor pattern SP. For example, the second conductive sub-patterns 164 may have a lower work-function than the conductive pattern 160, and may have a greater work-function than the second contact region CT2 of the semiconductor pattern SP. Accordingly, an electric field generated between the second contact region CT2 of the semiconductor pattern SP and the conductive pattern 160 of the gate electrode GE may be minimized, and as a result, gate-induced drain leakage (GIDL) between the second contact region CT2 of the semiconductor pattern SP, and the conductive pattern 160 of the gate electrode GE may be prevented or suppressed.

In addition, the semiconductor device according to the inventive concept may include a plurality of transistors stacked in a direction (for example, the third direction D3) vertical to the upper surface 100U of the substrate 100, and each of the plurality of transistors may include the gate electrode GE and the semiconductor pattern SP. Accordingly, the semiconductor device having improved electrical characteristics and easily high-integrated may be provided.

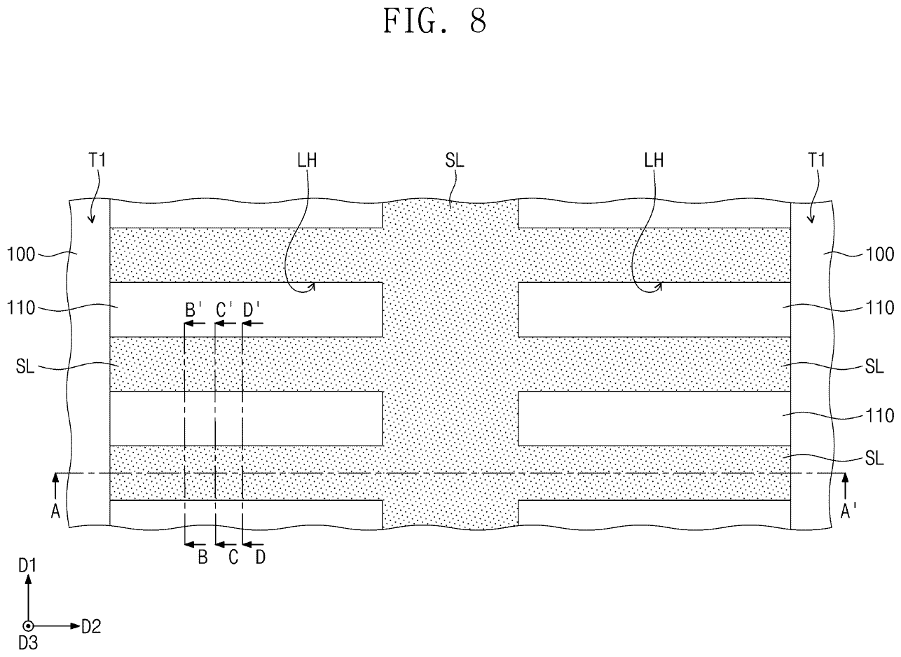

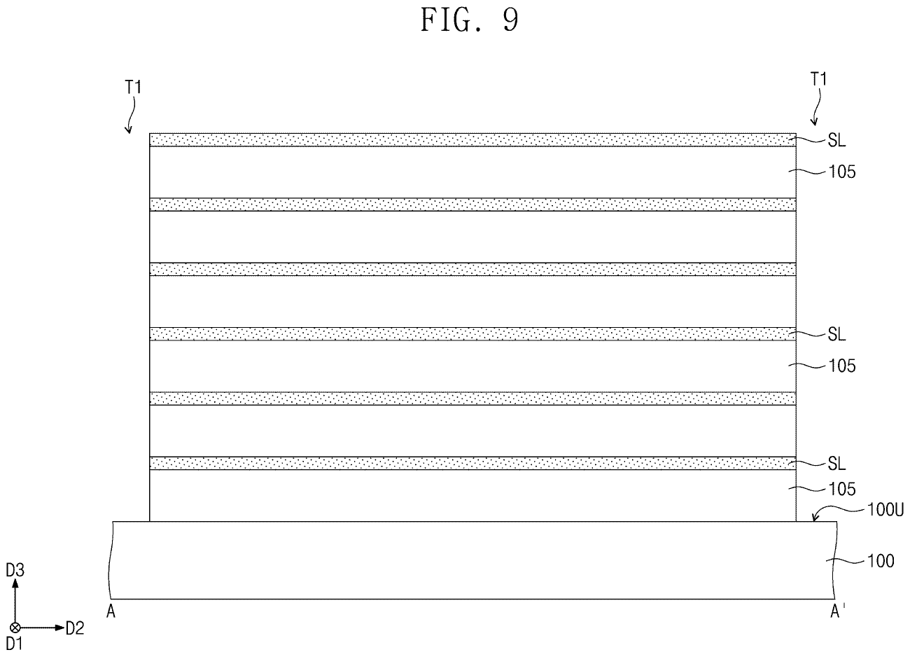

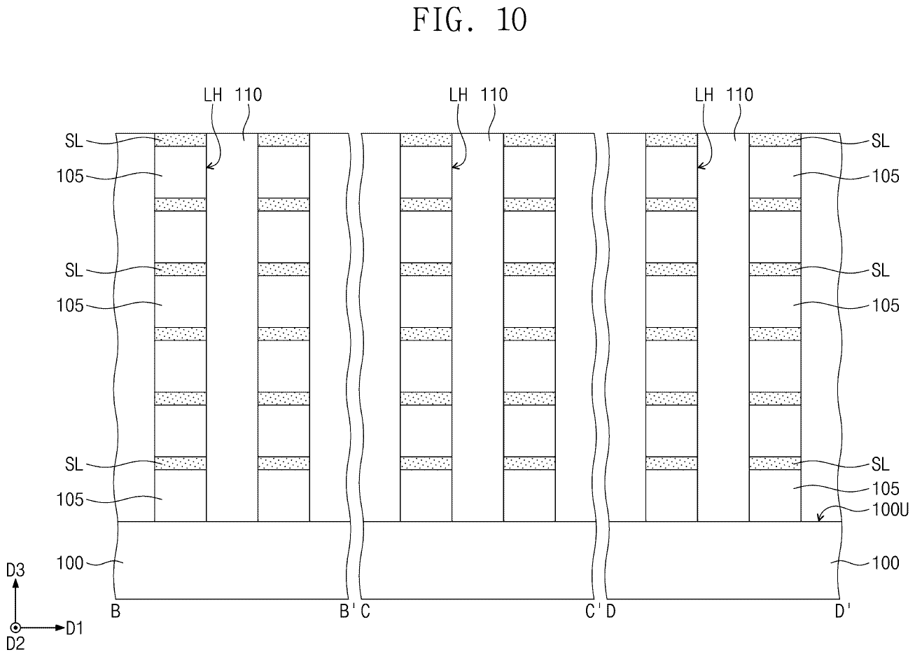

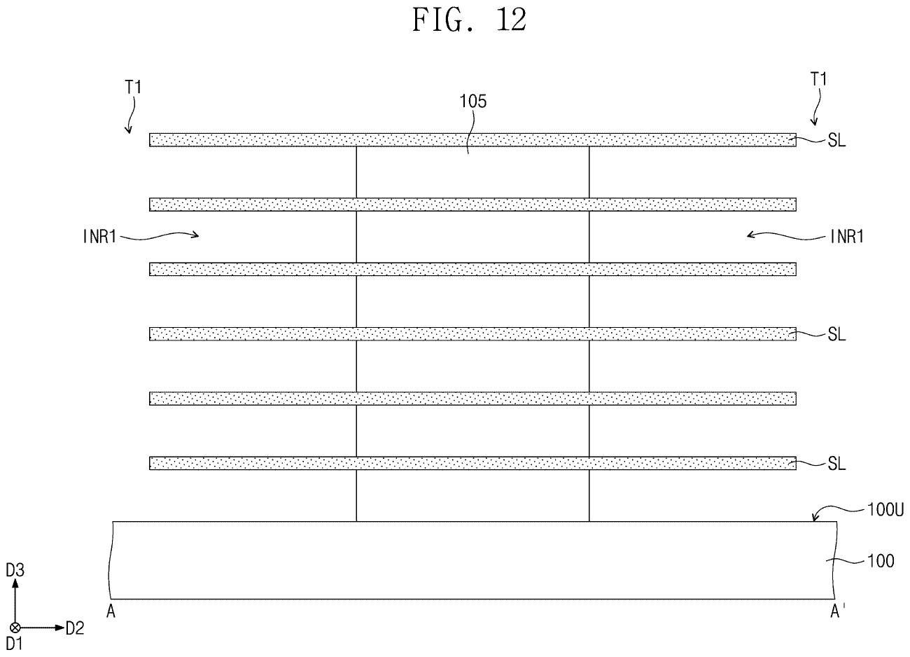

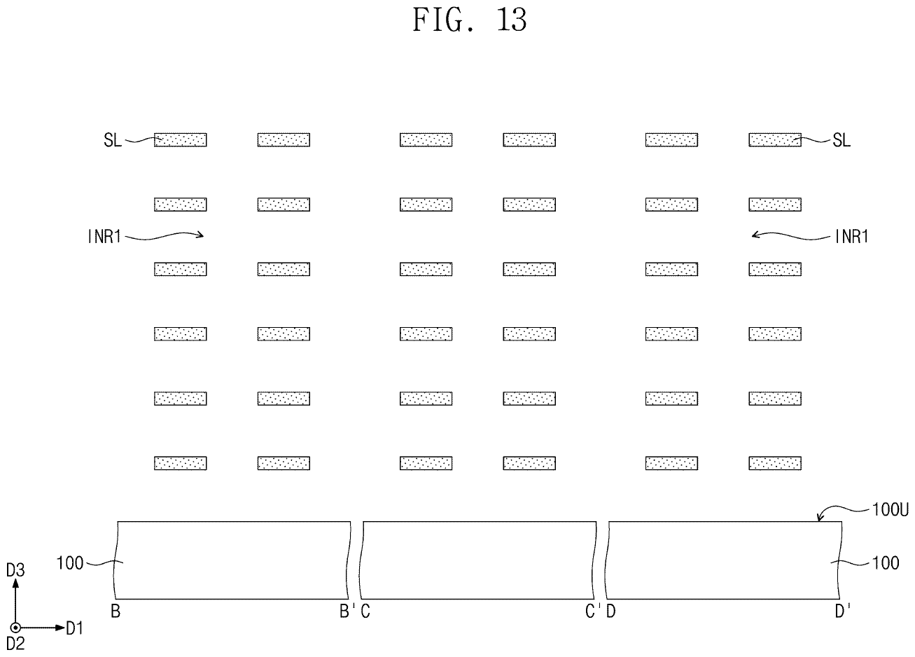

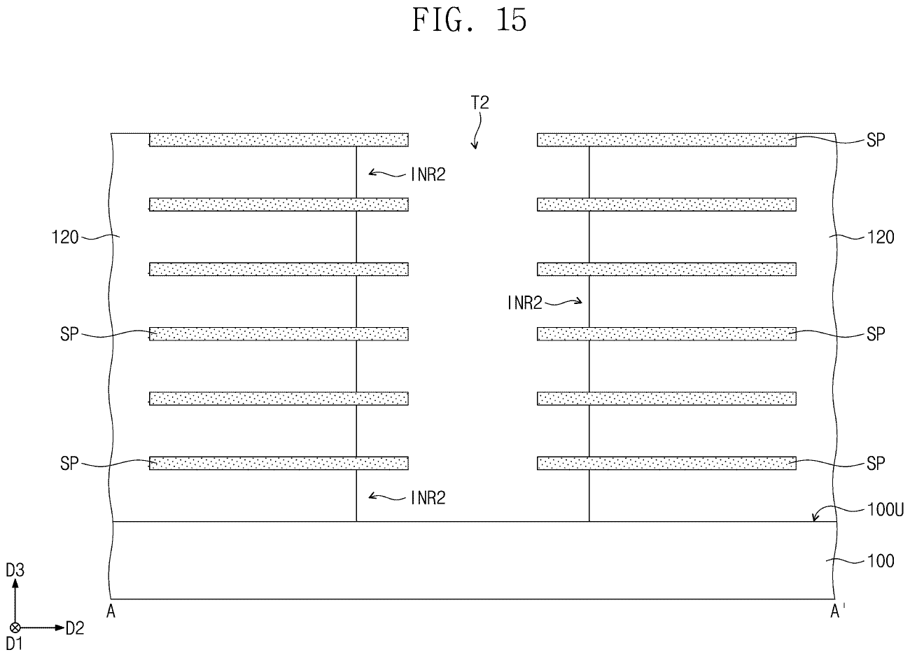

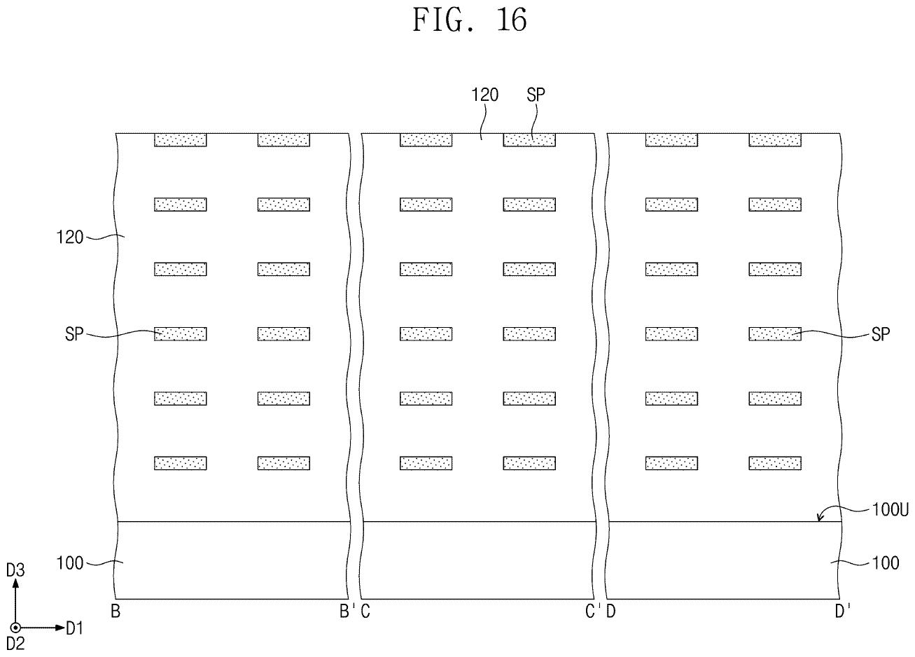

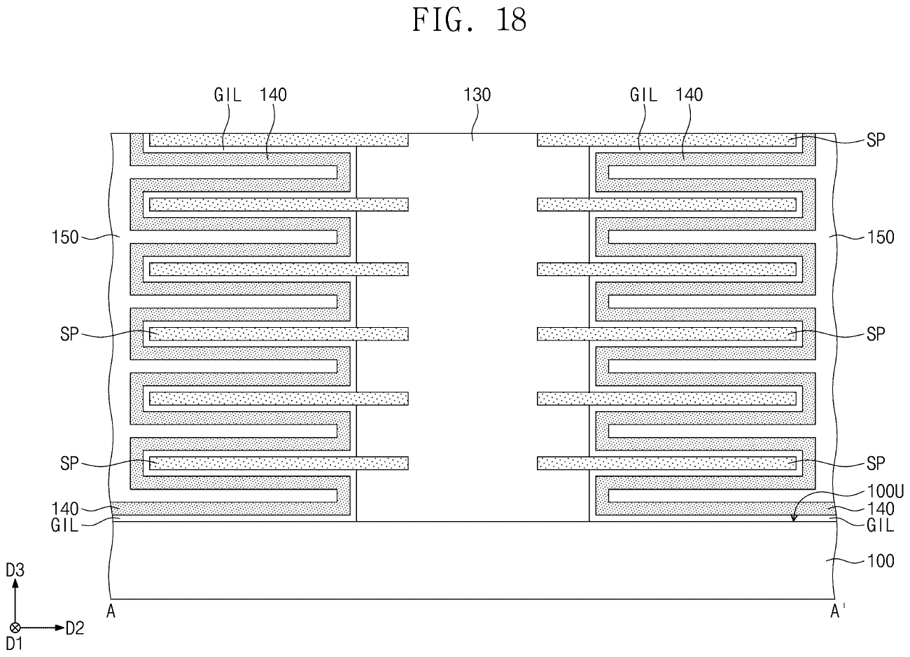

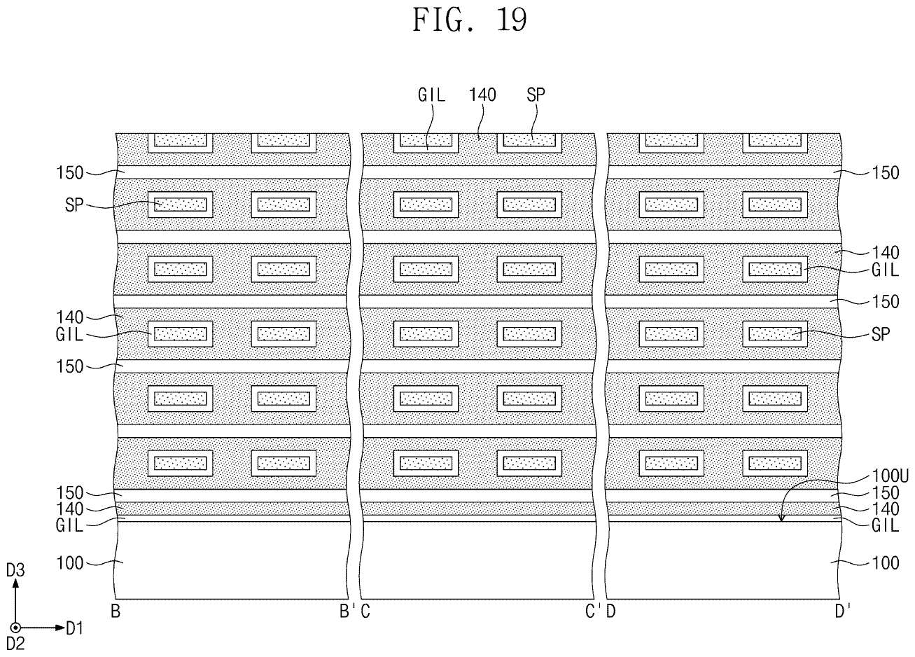

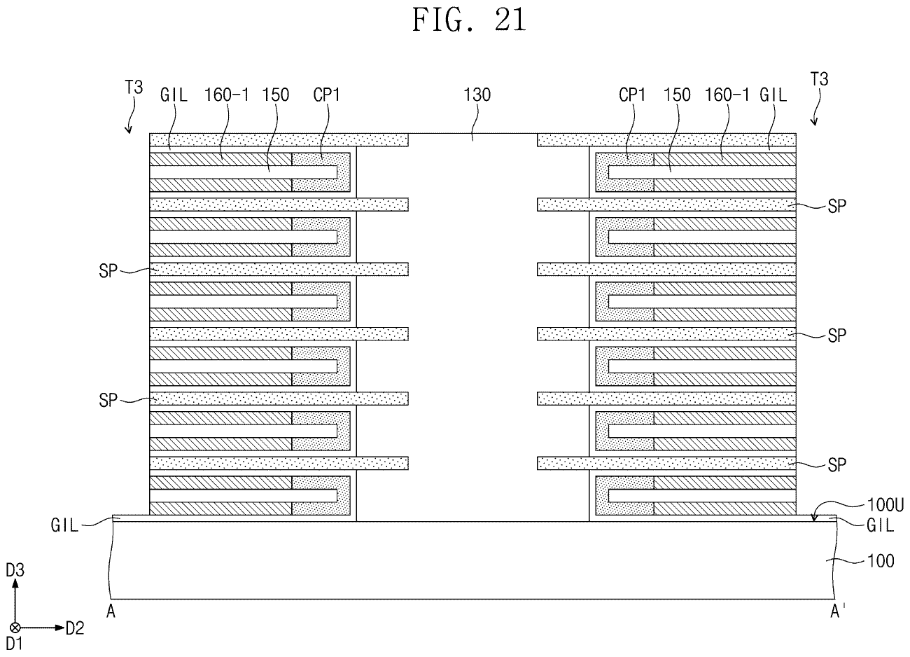

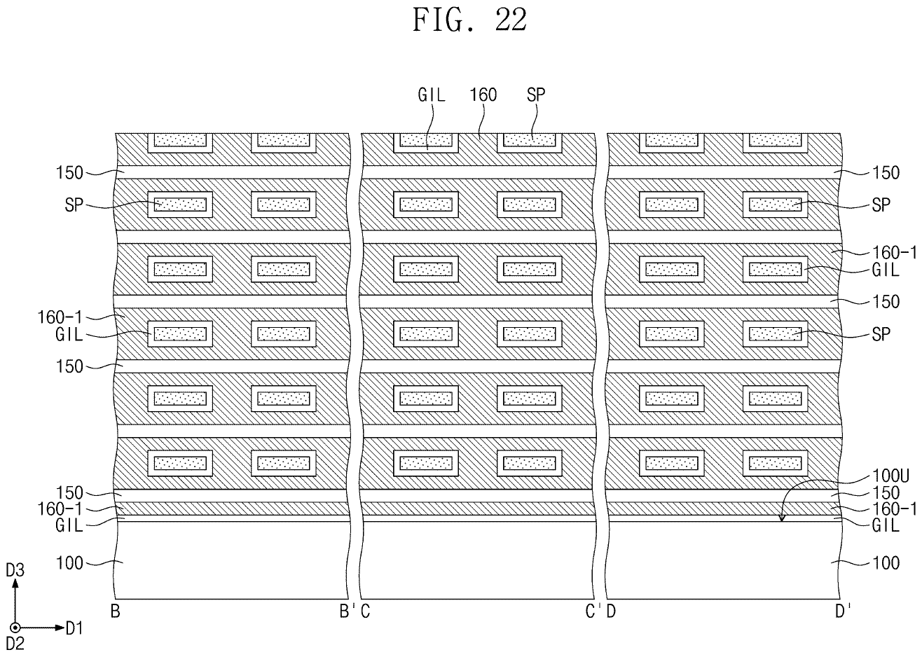

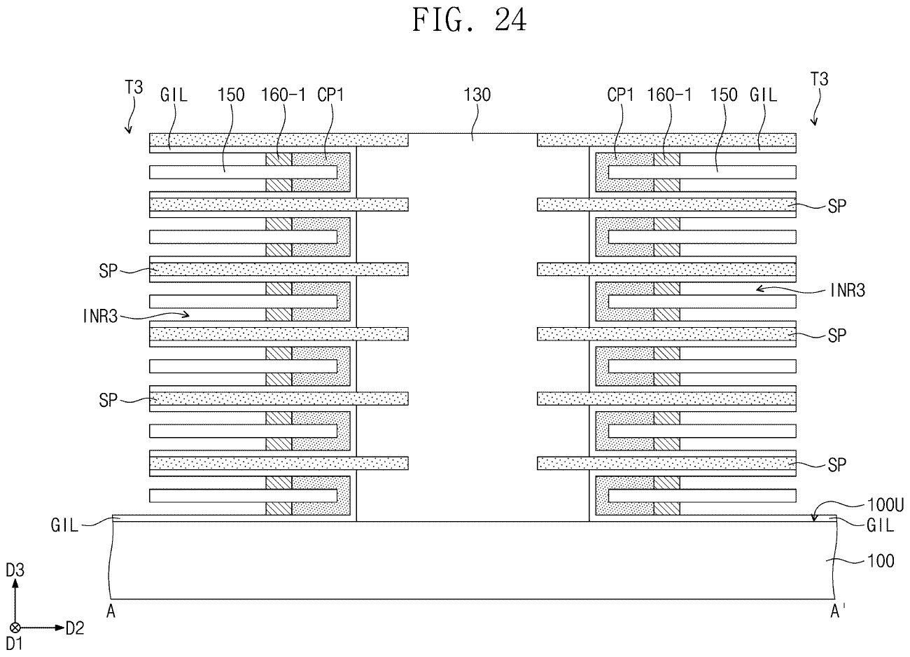

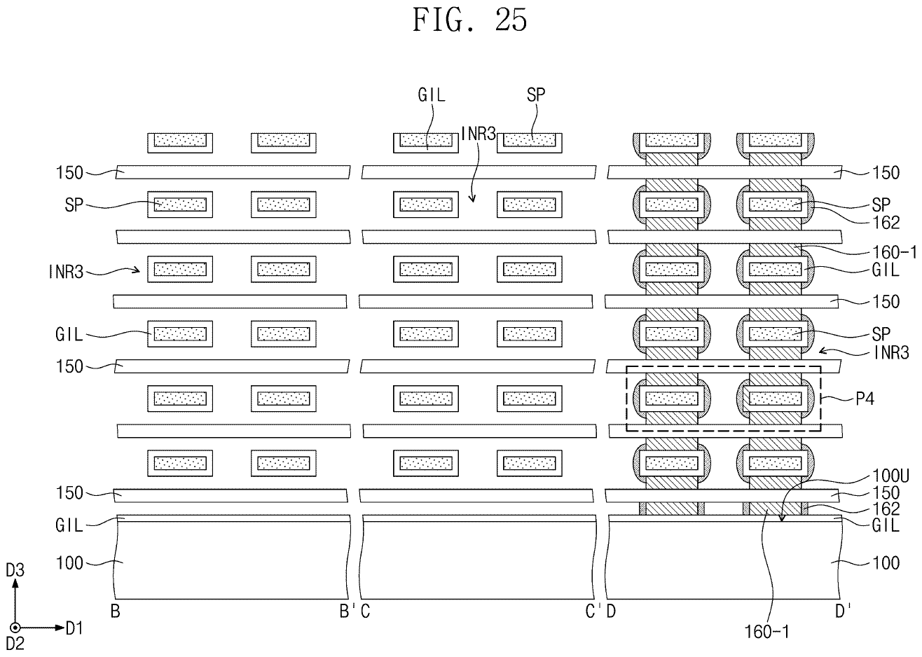

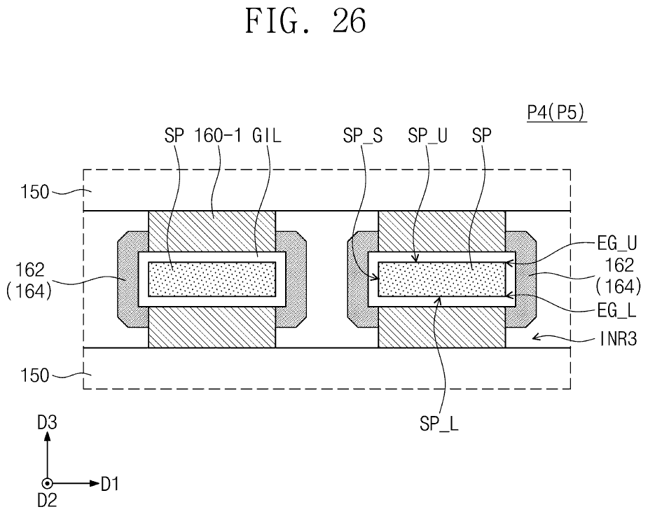

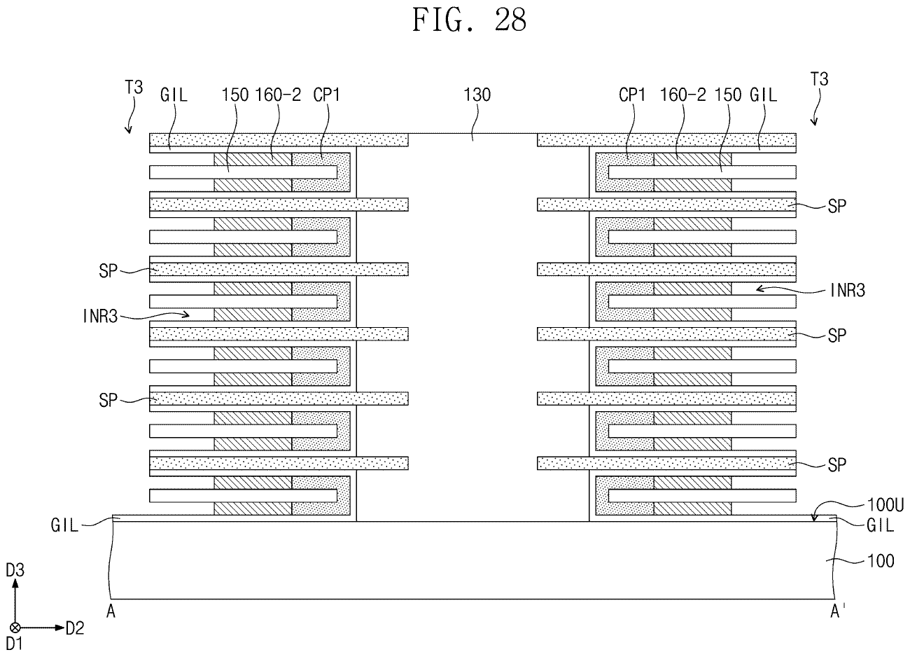

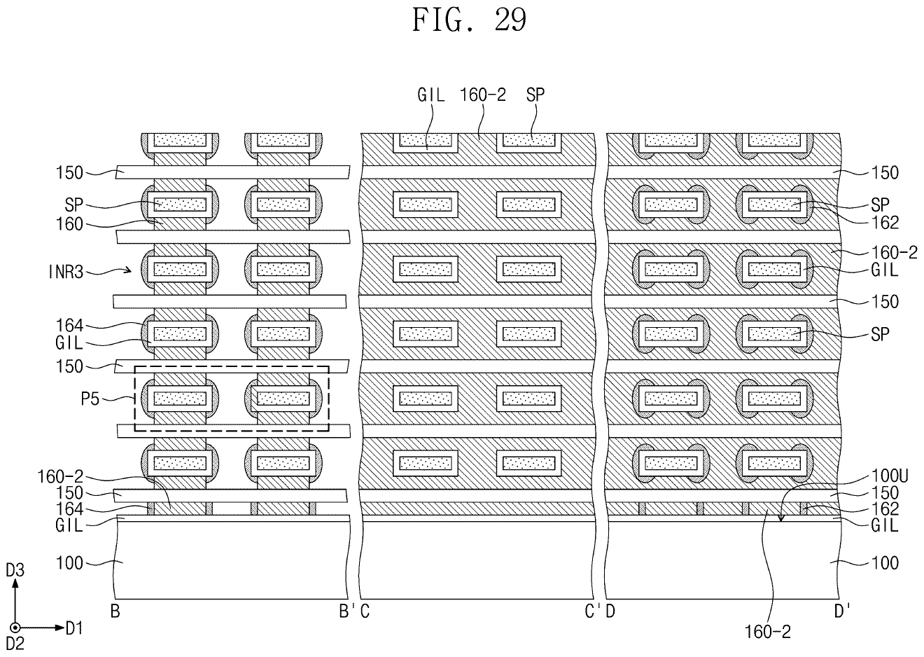

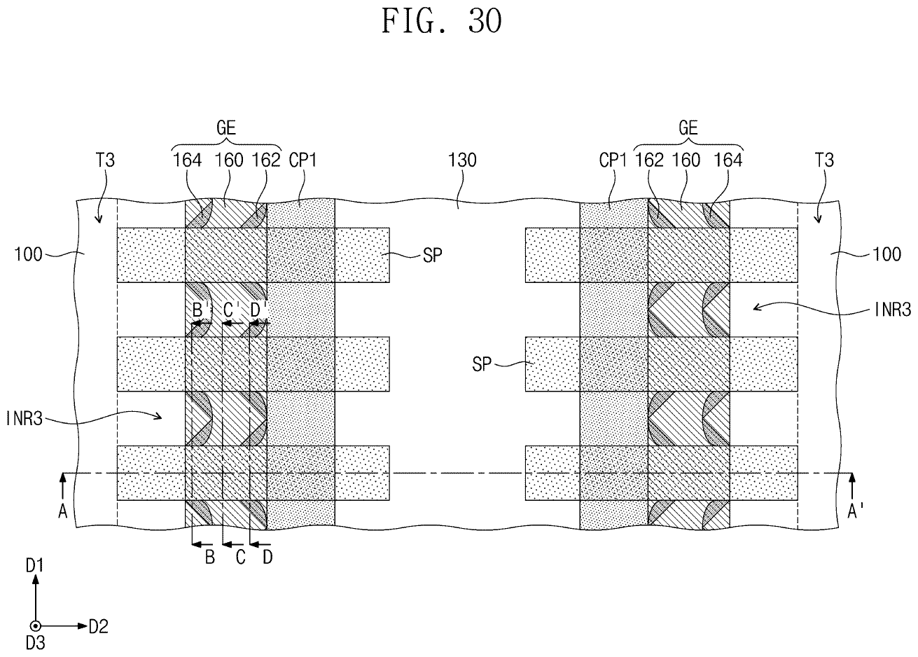

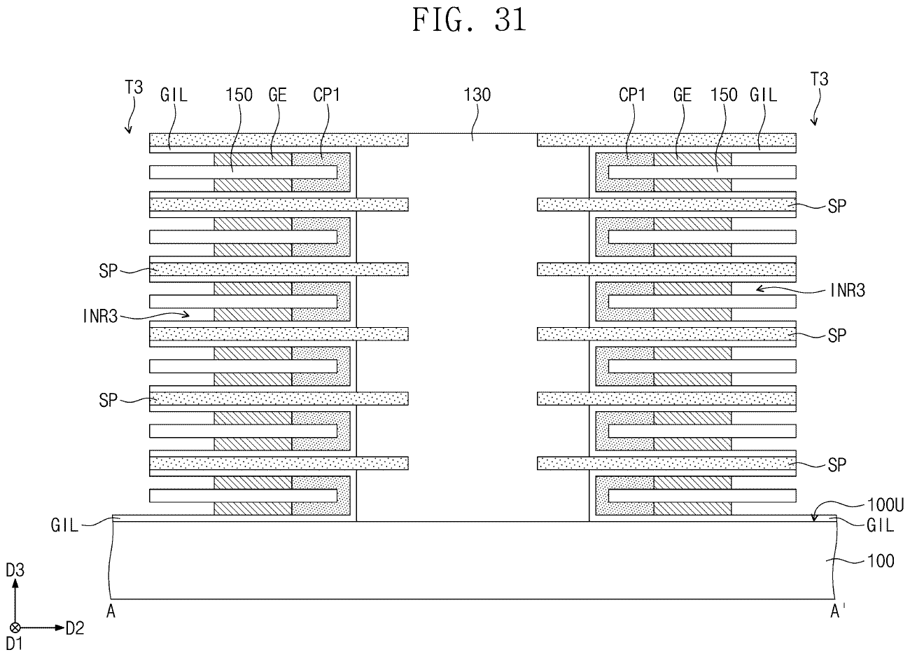

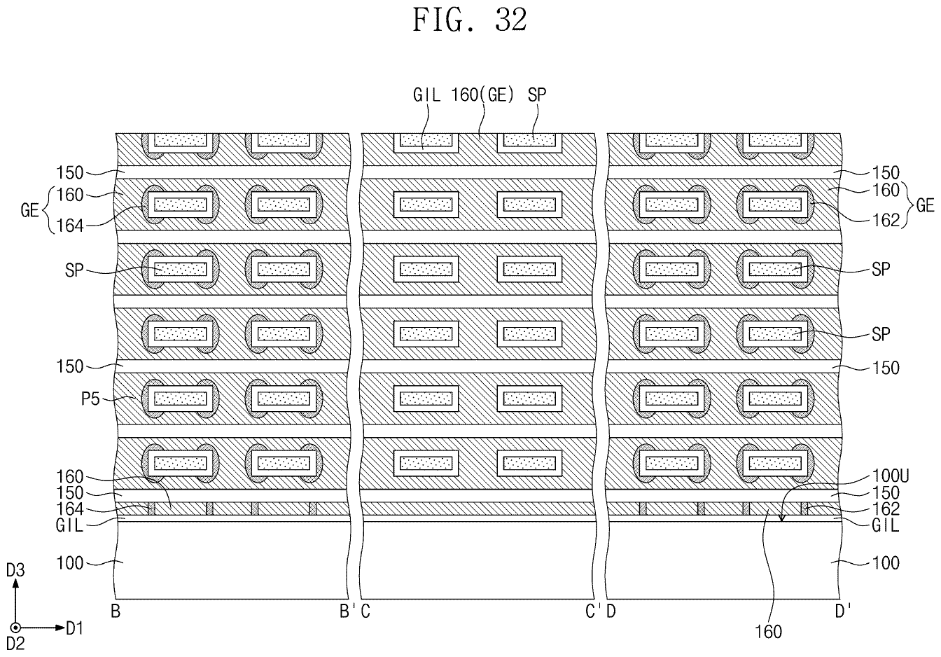

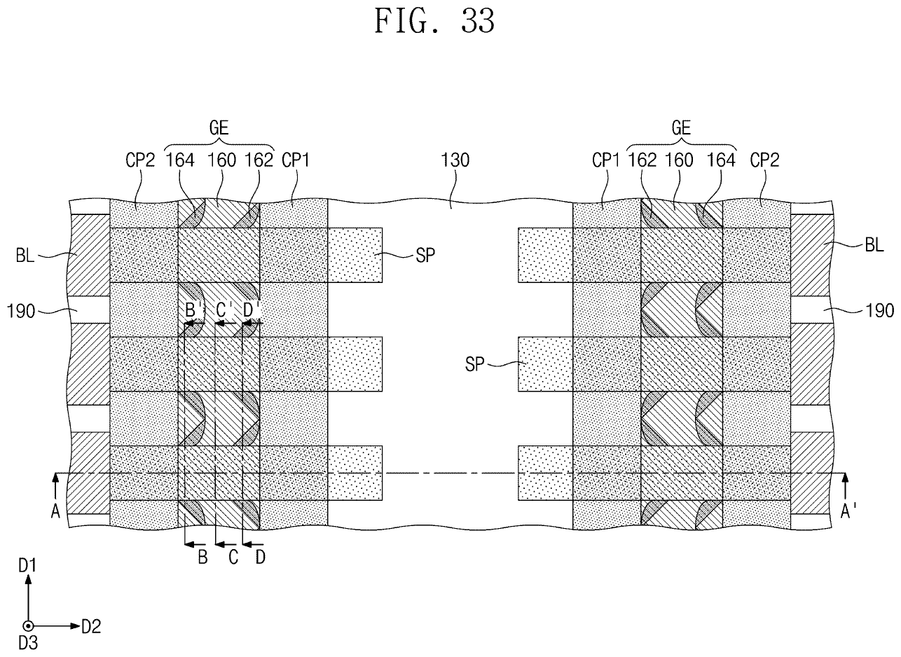

FIGS. 8, 11, 14, 17, 20, 23, 27, 30, 33, 35 and 37 are plan views illustrating a method for manufacturing a semiconductor device according to some embodiments of the inventive concept. FIGS. 9, 12, 15, 18, 21, 24, 28, 31, 34, 36 and 38 are cross-sectional views taken along A-A′ of FIGS. 8, 11, 14, 17, 20, 23, 27, 30, 33, 35 and 37, and FIGS. 10, 13, 16, 19, 22, 25, 29 and 32 are cross-sectional views taken along B-B′, C-C′ and D-D′ of FIGS. 8, 11, 14, 17, 20, 23, 27 and 30. The cross-sectional views taken along B-B′, C-C′ and D-D′ of FIGS. 33, 35 and 37 are substantially the same as that of FIG. 30. FIG. 26 is an enlarged diagram of part P4 of FIG. 25 and part P5 of FIG. 29. In order to simplify description, duplicate description for that of the semiconductor device made with reference to FIGS. 1 to 7 will be omitted.

Referring to FIGS. 8 to 10, sacrificial layers 105 and semiconductor layers SL may be alternately stacked on the substrate 100. The sacrificial layers 105 and the semiconductor layers SL may include a semiconductor material, and the sacrificial layers 105 may include a material having etching selectivity for the semiconductor layers SL. The semiconductor layers SL may include one of silicon (Si), germanium (Ge) and silicon-germanium (SiGe). The sacrificial layers 105 may include one of silicon (Si), germanium (Ge) and silicon-germanium (SiGe), but may include a material different from that of the semiconductor layers SL. For example, the semiconductor layers SL may include silicon (Si), and the sacrificial layers 105 may include silicon-germanium (SiGe). Each of the sacrificial layers 105 and the semiconductor layers SL may have a thickness along the third direction D3, and each of the sacrificial layers 105 may have a greater thickness than each of the semiconductor layers SL. A lowermost sacrificial layer 105 among the sacrificial layers 105 may be interposed between the substrate 100 and a lowermost semiconductor layer SL among the semiconductor layers SL. An uppermost semiconductor layer SL among the semiconductor layers SL may be disposed on an uppermost sacrificial layer 105 among the sacrificial layers 105.

Line holes LH may be formed so as to penetrate the sacrificial layers 105 and the semiconductor layers SL. The line holes LH may be spaced apart from each other in the first direction D1 and the second direction D2. Each of the line holes LH may extend in the third direction D3 to penetrate the sacrificial layers 105 and the semiconductor layers SL, and may expose the upper surface 100U of the substrate 100. The line holes LH may include a first column including the line holes LH spaced apart from each other in the first direction D1 and a second column including the line holes LH spaced apart from each other in the first direction D1, and the second column of the line holes LH may be spaced apart from the first column of the line holes LH in the second direction D2. The line holes LH of the first column may be respectively aligned with the line holes LH of the second column along the second direction D2. The sacrificial layers 105 and the semiconductor layers SL may extend long in the first direction D1 between the first column of the line holes LH and the second column of the line holes LH, and may extend long in the second direction D2 between the line holes LH of the first column and between the line holes LH of the second column.

First filling patterns 110 may be formed so as to respectively fill the line holes LH. The first filling patterns 110 may include an insulating material, and may include, for example, silicon oxide, silicon nitride and/or silicon oxynitride. The first filling patterns 110 may include a first column including the first filling patterns 110 spaced apart from each other in the first direction D1, and a second column including the first filling patterns 110 spaced apart from each other in the first direction D1. The second column of the first filling patterns 110 may be spaced apart from the first column of the first filling patterns 110 in the second direction D2. The first filling patterns 110 of the first column may be respectively aligned with the first filling patterns 110 of the second column along the second direction D2. The semiconductor layers SL and the sacrificial layers 105 may extend long in the first direction D1 between the first column of the first filling patterns 110 and the second column of the first filling patterns 110, and may extend long in the second direction D2 between the first filling patterns 110 of the first column, and between the first filling patterns 110 of the second column.

First trenches T1 may be formed so as to penetrate the sacrificial layers 105, the semiconductor layers SL and the first filling patterns 110. The first trenches T1 may extend in the first direction D1, and may be spaced apart from each other in the second direction D2. Each of the first trenches T1 may extend in the third direction D3 to penetrate the sacrificial layers 105, the semiconductor layers SL and the first filling patterns 110. Each of the first trenches T1 may expose the upper surface 100U of the substrate 100. The remaining portions of the sacrificial layers 105, the semiconductor layers SL and the first filling patterns 110 may be disposed between the first trenches T1. Each of the first trenches T1 may expose side surfaces of the sacrificial layers 105, the semiconductor layers SL and the first filling patterns 110.

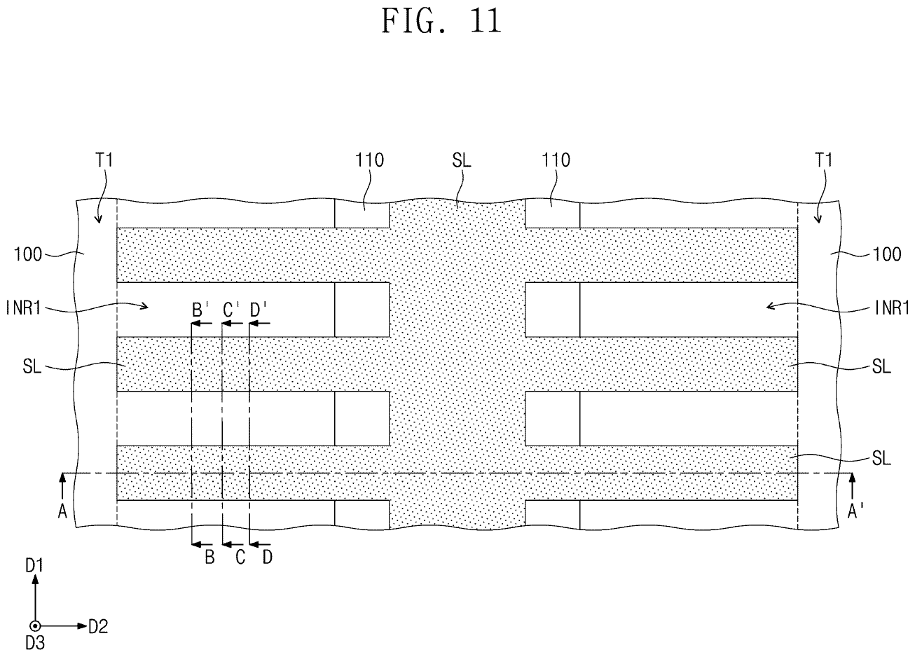

Referring to FIGS. 11 to 13, the side surfaces of the sacrificial layers 105 and the first filling patterns 110 exposed by the first trenches T1 may be laterally recessed. Accordingly, first recess regions INR1 may be formed. The first recess regions INR1 may be interposed between the semiconductor layers SL spaced apart from each other in the third direction D3, and may extend between the semiconductor layers SL spaced apart from each other in the first direction D1. A lowermost first recess region INR1 among the first recess regions INR1 may be interposed between the substrate 100 and a lowermost semiconductor layer SL among the semiconductor layers SL, and may expose the upper surface 100U of the substrate 100.

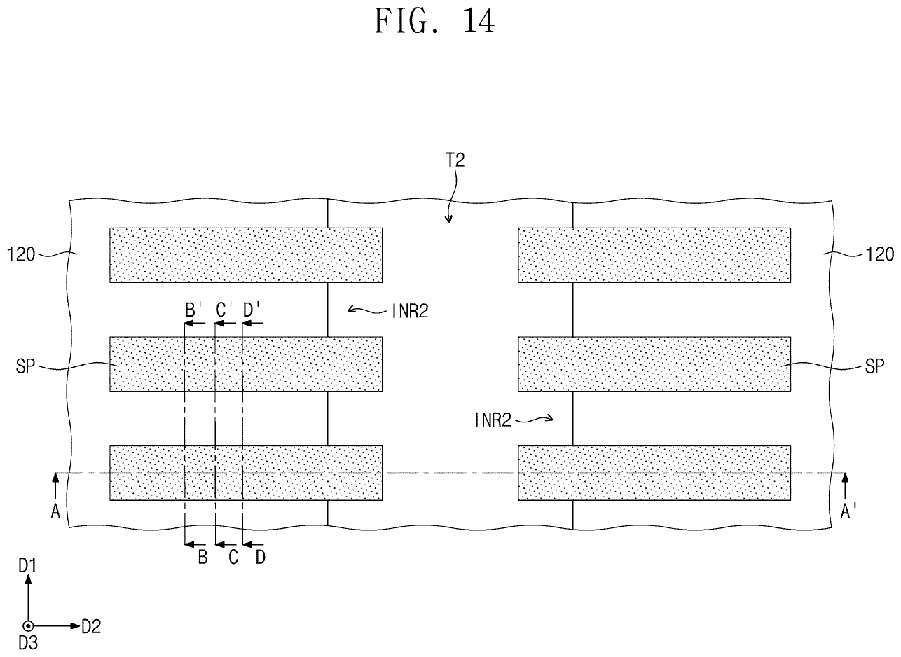

Referring to FIGS. 14 to 16, second filling patterns 120 may be formed so as to fill the first recess regions INR1 and the first trenches Ti. The second filling patterns 120 may include an insulating material, and may include, for example, silicon oxide, silicon nitride and/or silicon oxynitride.

A second trench T2 may be formed so as to penetrate the sacrificial layers 105 and the semiconductor layers SL. The second trench T2 may extend in the first direction D1 and the third direction D3, and may expose the upper surface 100U of the substrate 100. The semiconductor layers SL may be separated into a plurality of semiconductor patterns SP spaced apart from each other in the first direction D1, the second direction D2 and the third direction D3 by the second trench T2. Each of the semiconductor patterns SP may have a bar shape extending in the second direction D2. The second trench T2 may expose side surfaces of the sacrificial layers 105 and the first filling patterns 110.

The remaining portions of the sacrificial layers 105 and the first filling patterns 110 may be removed by laterally recessing the side surfaces of the sacrificial layers 105 and the first filling patterns 110 exposed by the second trench T2. Accordingly, second recess regions INR2 may be formed. The second recess regions INR2 may be interposed between the semiconductor patterns SP spaced apart from each other in the third direction D3, and may extend between the semiconductor patterns SP spaced apart from each other in the first direction D1. A lowermost second recess region INR2 among the second recess regions INR2 may be interposed between the substrate 100 and the lowermost semiconductor pattern SP among the semiconductor patterns SP, and may expose the upper surface 100U of the substrate 100. The second recess regions INR2 may expose side surfaces of the second filling patterns 120.

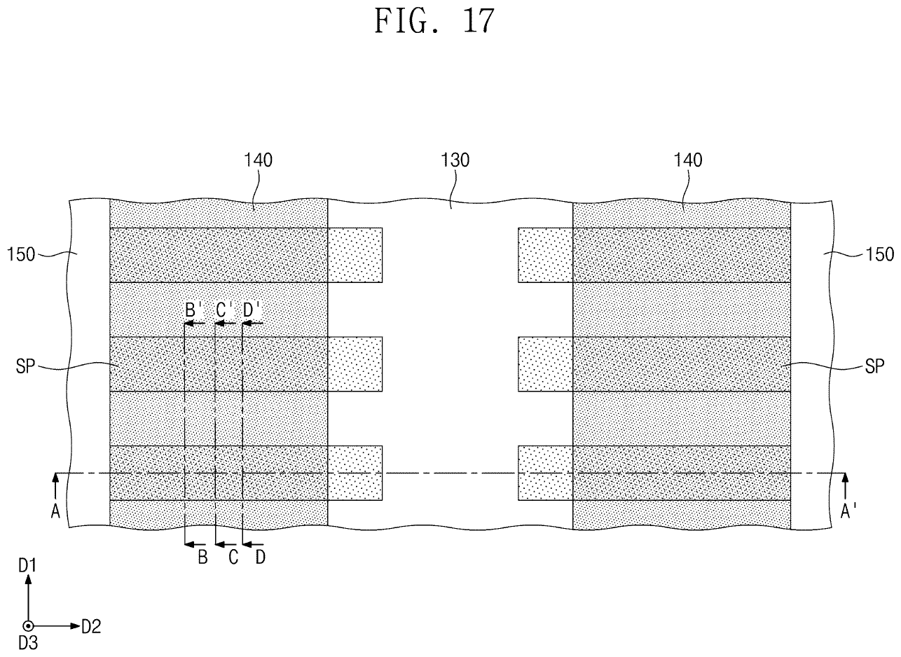

Referring to FIGS. 17 to 19, a third filling pattern 130 may be formed so as to fill the second trench T2 and the second recess regions INR2. The third filling pattern 130 may include an insulating material, and may include, for example silicon oxide, silicon nitride and/or silicon oxynitride. Thereafter, the second filling patterns 120 may be removed, and each of the semiconductor patterns SP may be partially exposed.

A preliminary gate insulating layer GIL may be formed so as to conformally cover exposed portions of the semiconductor patterns SP. The preliminary gate insulating layer GIL may extend so as to conformally cover the side surface of the third filling pattern 130 between the semiconductor patterns SP, a side surface of the third filling pattern 130 between the substrate 100 and lowermost semiconductor patterns SP among the semiconductor patterns SP, and the upper surface 100U of the substrate 100.

A capping insulating layer 140 may be formed on the preliminary gate insulating layer GIL, and may be formed so as to conformally cover the exposed portions of the semiconductor patterns SP. The capping insulating layer 140 may extend so as to conformally cover a side surface of the third filling pattern 130 between the semiconductor patterns SP, a side surface of the third filling pattern 130 between the substrate 100 and the lowermost semiconductor patterns SP among the semiconductor patterns SP, and the upper surface 100U of the substrate 100. The preliminary gate insulating layer GIL may be interposed between the capping insulating layer 140 and the exposed portions of the semiconductor patterns SP, between the capping insulating layer 140 and the side surfaces of the third filling pattern 130, and between the capping insulating layer 140 and the upper surface 100U of the substrate 100.

A mold insulating layer 150 may be formed so as to cover the exposed portions of the semiconductor patterns SP. The mold insulating layer 150 may extend in the second direction D2 between the exposed portions of the semiconductor patterns SP, and may extend in the second direction D2 between the substrate 100 and the lowermost semiconductor patterns SP among the semiconductor patterns SP. The preliminary gate insulating layer GIL and the capping insulating layer 140 may be interposed between the mold insulating layer 150 and the exposed portions of the semiconductor patterns SP, between the mold insulating layer 150 and the side surfaces of the third filling pattern 130, and between the mold insulating layer 150 and the upper surface 100U of the substrate 100.

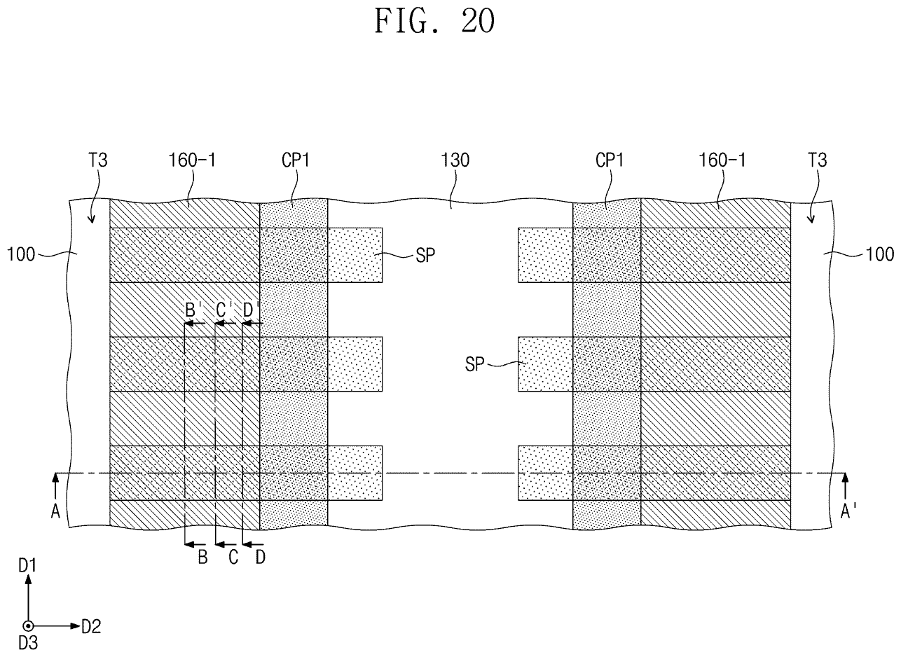

Referring to FIGS. 20 to 22, third trenches T3 may be formed so as to penetrate the mold insulating layer 150. The third trenches T3 may extend in the first direction D1, and may be spaced apart from each other in the second direction D2. Each of the third trenches T3 may extend in the third direction D3 to expose the preliminary gate insulating layer GIL on the upper surface 100U of the substrate 100. Each of the third trenches T3 may expose side surfaces of the semiconductor patterns SP, the preliminary gate insulating layer GIL, the capping insulating layer 140 and the mold insulating layer 150. The semiconductor patterns SP, the remaining portions of the preliminary gate insulating layer GIL, the remaining portions of the capping insulating layer 140, the remaining portions of the mold insulating layer 150 and the third filling pattern 130 may be disposed between the third trenches T3. The remaining portions of the mold insulating layer 150 may be referred to as mold patterns 150. The mold patterns 150 may extend between the semiconductor patterns SP in the first direction D1 and the second direction D2.

Side surfaces of the capping insulating layer 140 may be exposed by each of the third trenches T3. The Side surfaces of the capping insulating layer 140 may be laterally recessed. Accordingly, the first capping pattern CP1 may be formed. The first capping pattern CP1 may extend in the first direction D1, and may partially surround each of the semiconductor patterns SP. The first capping pattern CP1 may extend between the mold patterns 150 and side surfaces of the third filling pattern 130.

The side surfaces of the capping insulating layer 140 may be laterally recessed to form empty regions, and a first preliminary conductive layer 160-1 may be formed so as to fill the empty regions. Forming the first preliminary conductive layer 160-1 may include forming the first preliminary conductive layer 160-1 that fills the empty regions and that partially fills each of the third trenches T3, and removing a first portion of the first preliminary conductive layer 160-1 in each of the third trenches T3. Each of the third trenches T3 may expose side surfaces of the semiconductor patterns SP, the mold patterns 150, the preliminary gate insulating layer GIL and the conductive layer 160.

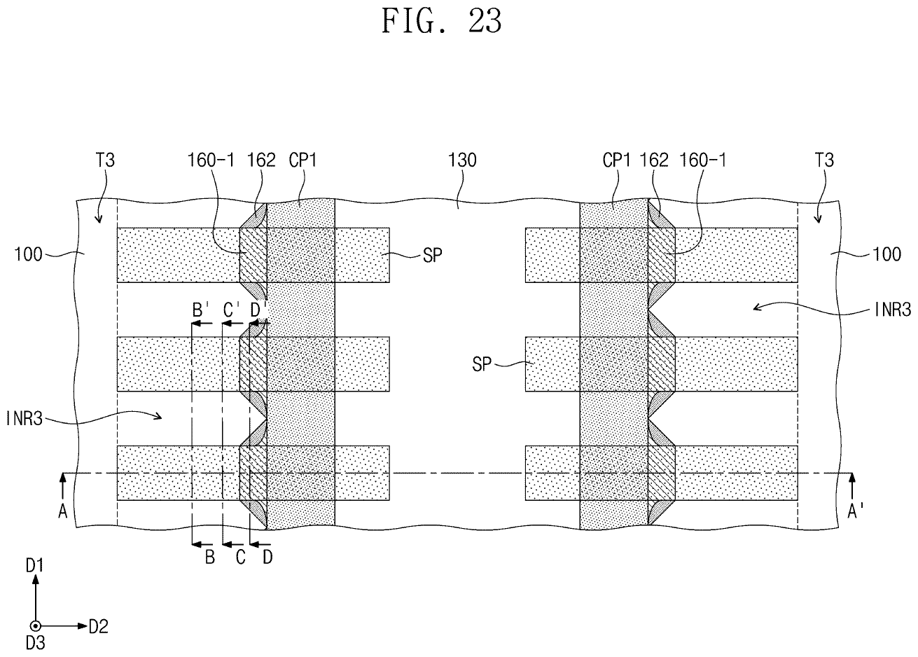

Referring to FIGS. 23 to 25, the side surfaces of the first preliminary conductive layer 160-1 may be exposed by each of the third trenches T3. The side surfaces of the first preliminary conductive layer 160-1 may be laterally recessed. Accordingly, third recess regions INR3 may be formed, and the remaining portion of the first preliminary conductive layer 160-1 may be left adjacent to the first capping pattern CP1.

Each of the third recess regions INR3 may surround each of the semiconductor patterns SP between a pair of mold patterns 150, adjacent to each other in the third direction D3, among the mold patterns 150. Each of the third recess regions INR3 may expose the preliminary gate insulating layer GIL on each of the semiconductor patterns SP.

Referring to FIGS. 23, 25 and 26, each of the semiconductor patterns SP may have side surfaces SP_S facing away from (or opposite to) each other in the first direction D1, and an upper surface SP_U and a lower surface SP_L opposite to each other in the third direction D3. The preliminary gate insulating layer GIL may cover the side surfaces SP_S, the upper surface SP_U and the lower surface SP_L of each of the semiconductor patterns SP. Each of the third recess regions INR3 may expose the preliminary gate insulating layer GIL on the side surfaces SP_S, the upper surface SP_U and the lower surface SP_L of each of the semiconductor patterns SP. The remaining portion of the first preliminary conductive layer 160-1 may be disposed adjacent to the first capping pattern CP1, and may be locally disposed on the upper surface SP_U and the lower surface SP_L of each of the semiconductor patterns SP. Accordingly, in a region adjacent to the first capping pattern CP1, the preliminary gate insulating layer GIL on the side surfaces SP_S, the upper edge EG_U and the lower edge EG_L of each of the semiconductor patterns SP may be exposed by each of the third recess regions INR3.

The first conductive sub-patterns 162 may be respectively formed on the side surfaces SP_S of each of the semiconductor patterns SP, and may be spaced apart from each other in the first direction D1. Forming the first conductive sub-patterns 162 may include forming a first conductive sub-layer that fills the third recess regions INR3, and laterally recessing the first conductive sub-layer through the third trenches T3. The first conductive sub-patterns 162 may be disposed adjacent to the first capping pattern CP1. The first conductive sub-patterns 162 may cover the preliminary gate insulating layer GIL on the side surfaces SP_S, the upper edge EG_U and the lower edge EG_L of each of the semiconductor patterns SP in a region adjacent to the first capping pattern CP1, and may at least partially cover the remaining portion of the first preliminary conductive layer 160-1.

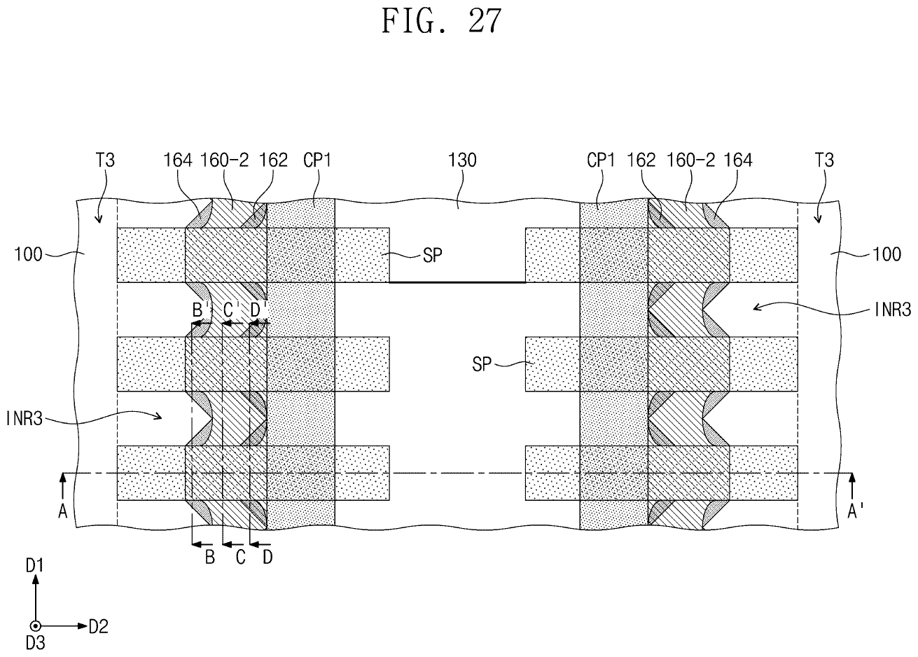

Referring to FIGS. 27 to 29, a first additional conductive layer may be formed so as to fill the third recess regions INR3 thereby forming a second preliminary conductive layer 160-2. Forming the second preliminary conductive layer 160-2 may include forming the first additional conductive layer that fills the third recess regions INR3, and that partially fills each of the third trenches T3, removing the first additional conductive layer in each of the third trenches T3, and laterally recessing the first additional conductive layer in each of the third recess regions INR3. As a result, the combination of the first preliminary conductive layer 160-1 and the remaining portion of the first additional conductive layer may form the second preliminary conductive layer 160-2. For example, the first preliminary conductive layer 160-1 and the first additional conductive layer may be formed of the same material, the second preliminary conductive layer 160-2 may be a single homogeneous body. The second preliminary conductive layer 160-2 may cover the first conductive sub-patterns 162, and may surround each of the semiconductor patterns SP between the pair of mold patterns 150.

Referring to FIGS. 26, 27 and 29, the second preliminary conductive layer 160-2 may be disposed locally (or partially) on the upper surface SP_U and the lower surface SP_L of each of the semiconductor patterns SP. Accordingly, the preliminary gate insulating layer GIL on the side surfaces SP_S, the upper edge EG_U and the lower edge EG_L of each of the semiconductor patterns SP may be exposed by each of the third recess regions INR3.

The second conductive sub-patterns 164 may be respectively formed on the side surfaces SP_S of each of the semiconductor patterns SP, and may be spaced apart from each other in the first direction D1. Forming the second conductive sub-patterns 164 may include forming a second conductive sub-layer that fills the third recess regions INR3, and laterally recessing the second conductive sub-layer through the third trenches T3. The first conductive sub-patterns 162 may be spaced apart from the second conductive sub-patterns 164 in the second direction D2. The second conductive sub-patterns 164 may cover the preliminary gate insulating layer GIL on the side surfaces SP_S, the upper edge EG_U and the lower edge EG_L of each of the semiconductor patterns SP, and may partially cover the second preliminary conductive layer 160-2.

Referring to FIGS. 30 to 32, a second additional conductive layer may be formed so as to fill the third recess regions INR3, thereby forming a conductive pattern 160. Forming the conductive pattern 160 may include forming the second additional conductive layer that fills the third recess regions INR3 and that partially fills each of the third trenches T3, removing a portion of the second additional conductive layer in each of the third trenches T3, and laterally recessing the second additional conductive layer in each of the third recess regions INR3. As a result, the combination of the second preliminary conductive layer 160-2 and the remaining portion of the second additional conductive layer may form the conductive patterns 160. For example, the second preliminary conductive layers 160-2 and the second additional conductive layer may be formed of the same material, the conductive patterns 160 may be a single homogeneous body. The conductive pattern 160 may cover the second conductive sub-patterns 164, and may surround each of the semiconductor patterns SP between the pair of mold patterns 150.

For example, the remaining portions of the first and second additional conductive layers and the first preliminary conductive layer 160-1 160-1 may collectively be referred to as the conductive pattern 160. The conductive pattern 160, the first conductive sub-patterns 162 and the second conductive sub-patterns 164 may constitute a gate electrode GE. The gate electrode GE may extend in the first direction D1, and may surround a corresponding one of the semiconductor patterns SP.

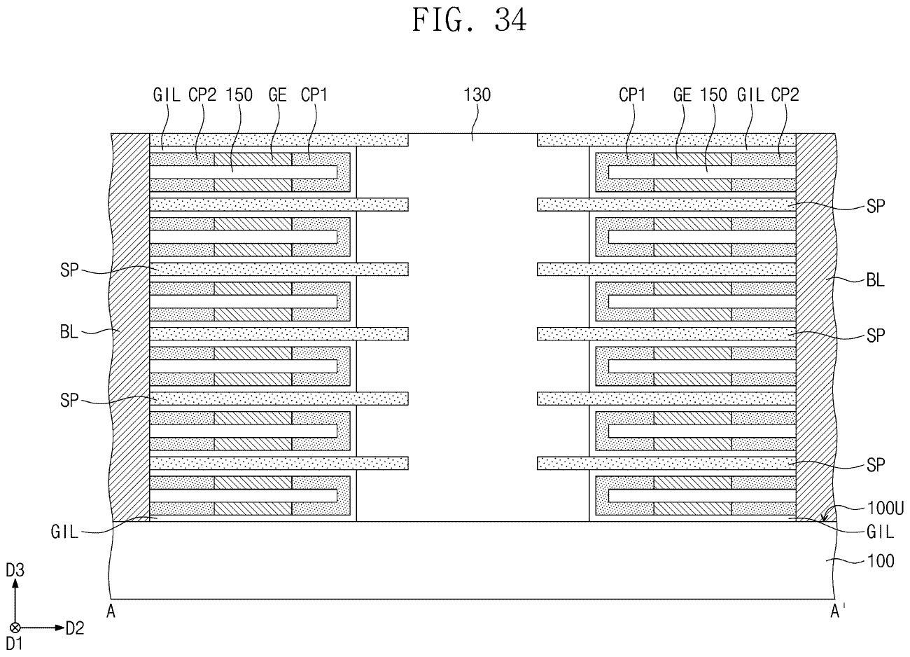

Referring to FIGS. 33 and 34, the second capping pattern CP2 may be formed so as to fill the third recess regions INR3. The second capping pattern CP2 may extend in the first direction D1, and may partially surround each of the semiconductor patterns SP. The preliminary gate insulating layer GIL may be interposed between the gate electrode GE and each of the semiconductor patterns SP, and may extend between the first capping pattern CP1 and each of the semiconductor patterns SP, and between the second capping pattern CP2 and each of the semiconductor patterns SP. The preliminary gate insulating layer GIL may further extend between the first capping pattern CP1 and the side surfaces of the third filling pattern 130.

The buried insulating layer 190 may be formed so as to fill each of the third trenches T3. For example, forming the buried insulating layer 190 may include partially removing the preliminary gate insulating layer GIL, exposed by each of the third trenches T3, from the upper surface 100U of the substrate 100, and forming the buried insulating layer 190 that fills each of the third trenches T3.

A plurality of bit lines BL may be formed so as to penetrate the buried insulating layer 190. The bit lines BL may be spaced apart from each other in the first direction D1. Each of the bit lines BL may penetrate the buried insulating layer 190 along the third direction D3. Each of the bit lines BL may extend in the third direction D3 to be electrically connected to the semiconductor patterns SP spaced apart from each other in the third direction D3.

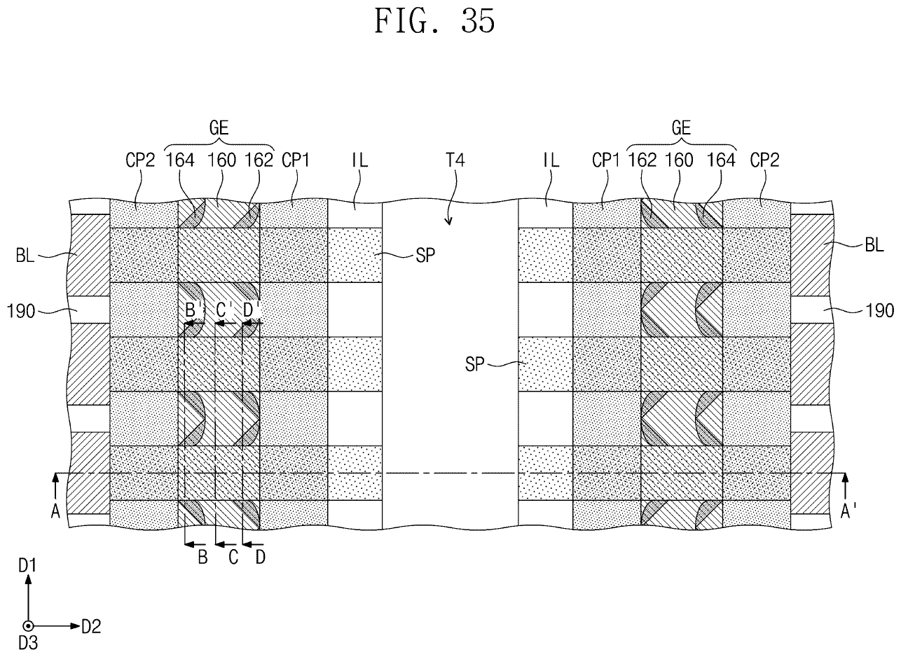

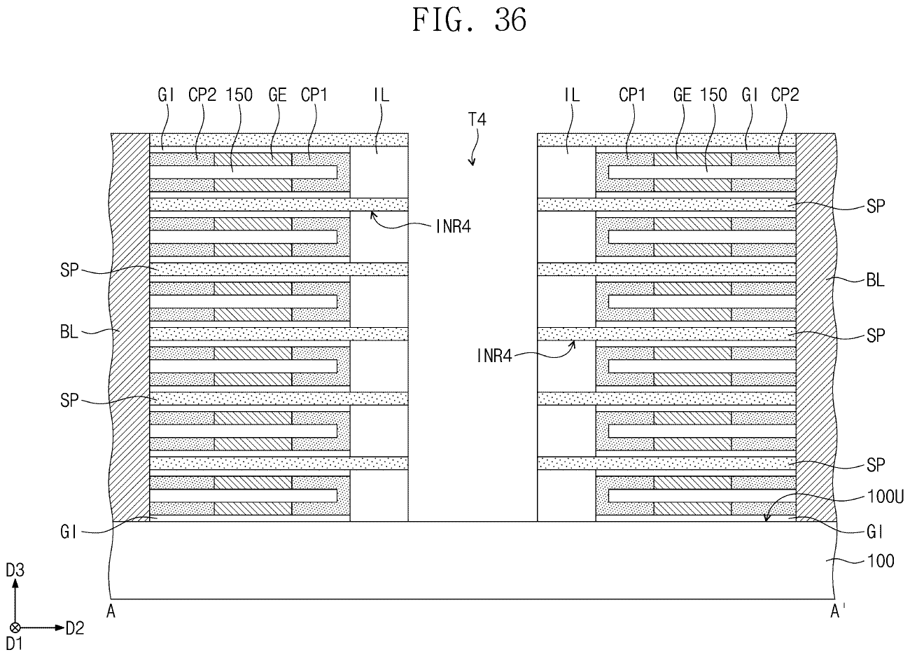

Referring to FIGS. 35 and 36, a fourth trench T4 may be formed so as to penetrate the third filling pattern 130. The fourth trench T4 may extend in the first direction D1, and may extend in the third direction D3 to expose the upper surface 100U of the substrate 100. The fourth trench T4 may expose side surfaces of the remaining portions of the third filling pattern 130 between the semiconductor patterns SP. The remaining portions of the third filling pattern 130 may be exposed by the fourth trench T4. The remaining portions of the third filling pattern 130 may be removed, and thus fourth recess regions INR4 may be formed between the semiconductor patterns SP. During forming the fourth recess regions INR4, the preliminary gate insulating layer GIL may be partially removed together. Accordingly, each of the fourth recess regions INR4 may expose the side surface of the first capping pattern CP1. The remaining portion of the preliminary gate insulating layer GIL may be referred to as a gate insulating layer GI.

The insulating layer IL may be formed so as to fill each of the fourth recess regions INR4. For example, forming the insulating layer IL may include forming the insulating layer IL that fills each of the fourth recess regions INR4, and that at least partially fills the fourth trench T4, and removing the insulating layer IL in the fourth trench T4. The insulating layer IL may surround an end portion of each of the semiconductor patterns SP. The fourth trench T4 may expose side surfaces of the end portions of the semiconductor patterns SP.

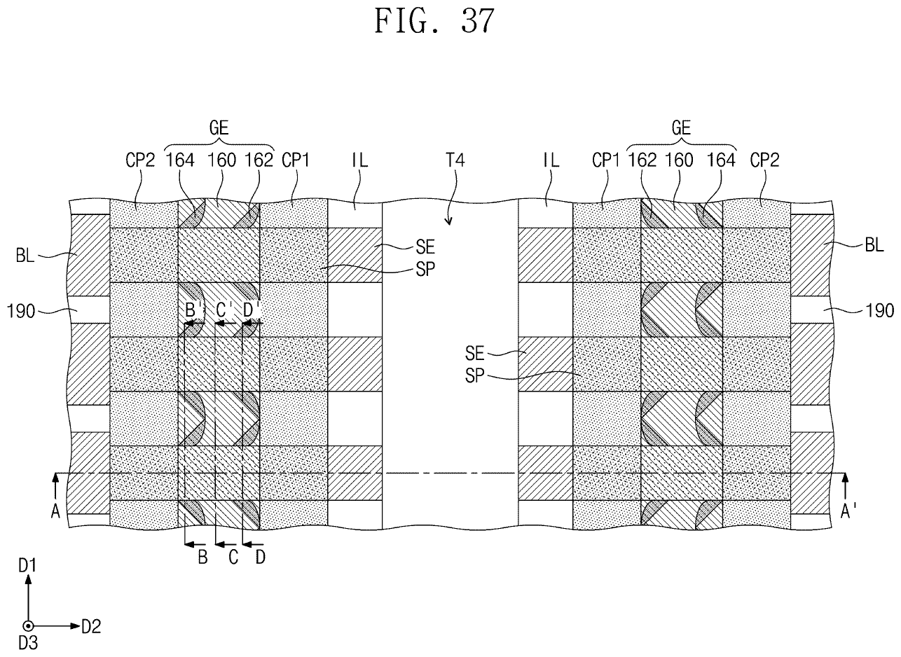

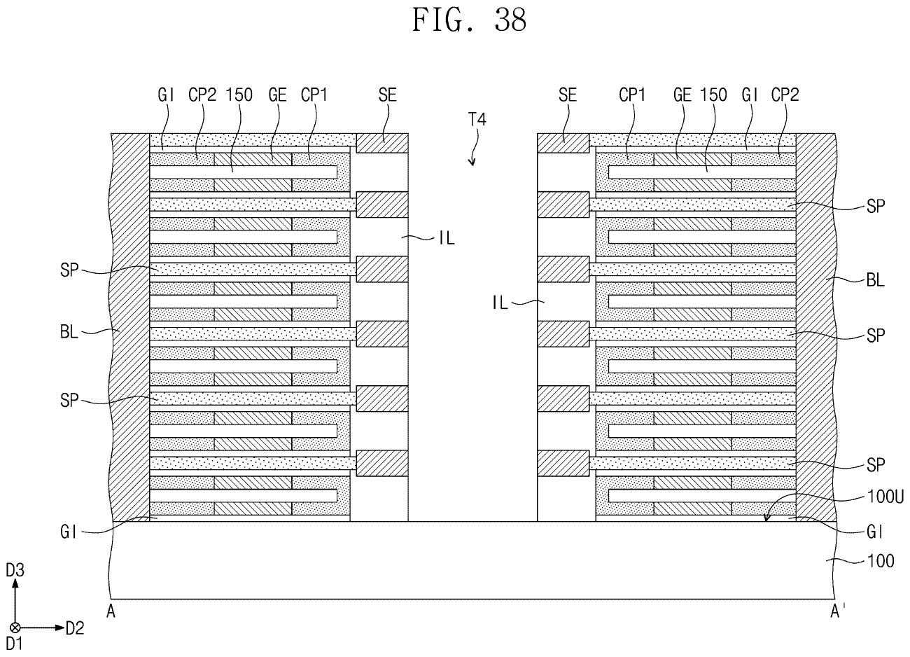

Referring to FIGS. 37 and 38, the exposed side surfaces of the end portions of the semiconductor patterns SP may be laterally recessed, and thus empty regions respectively exposing the semiconductor patterns SP may be formed in the insulating layer IL. A plurality of storage electrodes SE may be formed so as to respectively fill the empty regions. The plurality of storage electrodes SE may be respectively electrically connected to the plurality of semiconductor patterns SP. The fourth trench T4 may expose side surfaces of the plurality of storage electrodes SE and a side surface of the insulating layer IL.

Referring back to FIGS. 3 to 5, the side surface, of the insulating layer IL, exposed by the fourth trench T4, may be laterally recessed, and thus upper surfaces and lower surfaces of the plurality of storage electrodes SE may be exposed. The dielectric layer 200 may be formed so as to conformally cover the side surfaces, the upper surfaces and the lower surfaces of the plurality of storage electrodes SE. The remaining portion of the insulating layer IL may be left between the first capping pattern CP1 and the dielectric layer 200. The plate electrode PE may be formed so as to fill the fourth trench T4. The plate electrode PE may extend to a space between the plurality of storage electrodes SE, and the dielectric layer 200 may be interposed between the plate electrode PE and each of the plurality of storage electrodes SE. The plurality of storage electrodes SE, the dielectric layer 200 and the plate electrode PE may constitute the data storage pattern DSP. For example, the data storage pattern DSP may be a capacitor.

According to the inventive concept, a gate electrode may extend in a first direction, and a semiconductor pattern may extend in a second direction to penetrate the gate electrode. The semiconductor pattern may include contact regions disposed on both sides (e.g., opposite sides) of the gate electrode, and an active region present between the contact regions and overlapping the gate electrode. The gate electrode may include a conductive pattern, and conductive sub-patterns having a work-function different from that of the conductive pattern. The conductive sub-patterns may be spaced apart from each other in the first direction with the active region of the semiconductor pattern therebetween, and may be disposed adjacent to a corresponding contact region among the contact regions. The work-function of the conductive sub-patterns may be between a work-function of the conductive pattern and a work-function of the corresponding contact region. Accordingly, an electric field generated between the conductive pattern of the gate electrode and the corresponding contact region of the semiconductor pattern may be minimized, and as a result, gate-induced drain leakage (GIDL) between the conductive pattern of the gate electrode and the corresponding contact region of the semiconductor pattern may be prevented or suppressed.

In addition, the semiconductor pattern and the gate electrode may constitute a transistor, and a plurality of transistors may be vertically stacked on a substrate.

Accordingly, a semiconductor device having improved electrical characteristics and high-integration density (and a method for manufacturing the same) may be provided.

The above description of embodiments of the inventive concept provides an example for description of the inventive concept. Therefore, the inventive concept is not limited to the above embodiments, and various modifications and changes such as combining the above embodiments may be made by those skilled in the art within the technical spirit of the inventive concept.

What is claimed is:

1. A semiconductor device comprising:
a gate electrode extending on a substrate in a first direction;
a semiconductor pattern extending in a second direction and penetrating the gate electrode, wherein the first direction and the second direction are parallel to an upper surface of the substrate and cross each other; and
a gate insulating layer between the gate electrode and the semiconductor pattern,
wherein the semiconductor pattern has side surfaces, an upper surface and a lower surface,
wherein the side surfaces of the semiconductor pattern face away from each other in the first direction,
wherein the upper and lower surfaces of the semiconductor pattern face away from each other in a third direction perpendicular to the upper surface of the substrate,
wherein the gate electrode includes:
conductive sub-patterns each disposed on the side surfaces of the semiconductor pattern, and the conductive sub-patterns being spaced apart from each other in the first direction, and
a conductive pattern extending in the first direction, the conductive pattern covering the upper and lower surfaces of the semiconductor pattern, and the conductive pattern covering the conductive sub-patterns, and
wherein the conductive sub-patterns have a work-function different from that of the conductive pattern.

2. The semiconductor device of claim 1, wherein the conductive sub-patterns have a work-function lower than that of the conductive pattern.

3. The semiconductor device of claim 1, wherein:
each of the conductive sub-patterns extends along and covers an upper edge that is disposed between the upper surface of the semiconductor pattern and a corresponding one of the side surfaces of the semiconductor pattern, and
each of the conductive sub-patterns extends along and covers a lower edge between the lower surface and a corresponding one of the side surfaces of the semiconductor pattern.

4. The semiconductor device of claim 1, wherein:
the gate insulating layer is interposed between the side surfaces of the semiconductor pattern and the conductive sub-patterns,
the gate insulating layer is disposed between the upper surface of the semiconductor pattern and the conductive pattern, and
the gate insulating layer disposed between the lower surface of the semiconductor pattern and the conductive pattern.

5. The semiconductor device of claim 4, wherein:
the conductive pattern is disposed between the conductive sub-patterns, and
the conductive pattern is in contact with the gate insulating layer.

6. The semiconductor device of claim 1,
wherein the semiconductor pattern comprises:
a first contact region and a second contact region disposed on opposite sides of the gate electrode in the second direction; and
an active region overlapping the gate electrode as viewed from the first and third directions, the active region being interposed between the first contact region and the second contact region,
wherein the active region comprises a first boundary region adjacent to the first contact region, a second boundary region adjacent to the second contact region, and a channel region between the first boundary region and the second boundary region,
wherein, in the second direction, the conductive sub-patterns are disposed adjacent to one of the first boundary region and the second boundary region, and
wherein the first and second boundary regions have the same conductive type as the first and second contact regions, and doping concentrations of the first and second contact regions are greater than those of first and second boundary regions.

7. The semiconductor device of claim 6, further comprising:
a data storage pattern electrically connected to the first contact region of the semiconductor pattern; and
a bit line electrically connected to the second contact region of the semiconductor pattern.

8. The semiconductor device of claim 6, wherein, as viewed from the first direction, the conductive sub-patterns overlap one of the first boundary region and the second boundary region.

9. The semiconductor device of claim 8,
wherein the gate insulating layer is interposed between the conductive sub-patterns and side surfaces of one of the first and second boundary regions of the semiconductor pattern,
wherein the gate insulating layer extends onto side surfaces of the channel region of the semiconductor pattern, and
wherein the gate insulating layer is in contact with the side surfaces of the channel region of the semiconductor pattern.

10. The semiconductor device of claim 6,
wherein the conductive sub-patterns have a work-function greater than those of the first contact region and the second contact region of the semiconductor pattern, and
wherein the conductive sub-patterns have a lower work-function than the conductive pattern.

11. The semiconductor device of claim 6, wherein the conductive sub-patterns have the same conductive type as the first contact region and the second contact region.

12. A semiconductor device comprising:
a gate electrode extending on a substrate in a first direction; and
a semiconductor pattern extending in a second direction and penetrating the gate electrode,
wherein the first direction and the second direction are parallel to an upper surface of the substrate, and the first direction and the second direction cross each other,
wherein the semiconductor pattern includes:
a first contact region and a second contact region disposed on opposite sides of the gate electrode in the second direction, and
an active region overlapping the gate electrode as viewed from the first and third directions, the active region being interposed between the first contact region and the second contact region,
wherein the active region includes:
a first boundary region adjacent to the first contact region,
a second boundary region adjacent to the second contact region, and
a channel region between the first boundary region and the second boundary region,
wherein the gate electrode includes:
first conductive sub-patterns spaced apart from each other in the first direction with the first boundary region of the semiconductor pattern therebetween, and
a conductive pattern extending in the first direction, the conductive pattern surrounding the active region of the semiconductor pattern, and the conductive pattern covers the first conductive sub-patterns,
wherein the first conductive sub-patterns are interposed between the conductive pattern and the first boundary region of the semiconductor pattern,
wherein the first conductive sub-patterns have a work-function different from that of the conductive pattern, and
wherein the first and second boundary regions have the same conductive type as the first and second contact regions, and doping concentrations of the first and second contact regions are greater than those of first and second boundary regions.

13. The semiconductor device of claim 12, wherein the first conductive sub-patterns have a work-function different from that of the first contact region of the semiconductor pattern.

14. The semiconductor device of claim 13, wherein the first conductive sub-patterns have the same conductive type as the first contact region of the semiconductor pattern.

15. The semiconductor device of claim 12, wherein the first conductive sub-patterns have a lower work-function than the conductive pattern.

16. The semiconductor device of claim 15, wherein the first conductive sub-patterns have a greater work-function than the first contact region of the semiconductor pattern.

17. The semiconductor device of claim 12, wherein the first conductive sub-patterns have an N-type conductive type.

18. The semiconductor device of claim 12,
wherein the first boundary region of the semiconductor pattern overlaps the first conductive sub-patterns along the first direction, and
wherein the channel region of the semiconductor pattern does not overlap the first conductive sub-patterns along the first direction.

19. The semiconductor device of claim 12, further comprising a gate insulating layer between the semiconductor pattern and the gate electrode,
wherein the semiconductor pattern has side surfaces facing away from each other in the first direction, and an upper surface and a lower surface facing away from each other in a third direction vertical to the upper surface of the substrate,
wherein the gate insulating layer extends along the upper, lower and side surfaces of the semiconductor pattern,
wherein a first portion of the gate insulating layer, which is disposed on side surfaces of the first boundary region of the semiconductor pattern, is in contact with the first conductive sub-patterns, and
wherein a second portion of the gate insulating layer, which is disposed on side surfaces of the channel region of the semiconductor pattern, is in contact with the conductive pattern.

20. The semiconductor device of claim 12,
wherein the gate electrode further includes second conductive sub-patterns spaced apart from each other in the first direction with the second boundary region of the semiconductor pattern therebetween,
wherein the second conductive sub-patterns are spaced apart from the first conductive sub-patterns in the second direction, and
wherein the second conductive sub-patterns have a work-function different from that of the conductive pattern.
